(19) United States
(12) Patent Application Publication
(10) Pub. No.: US 2021/0119007 A1
(43) Pub. Date: Apr. 22, 2021

(54) THIN FILM TRANSISTOR SUBSTRATE, LIQUID CRYSTAL DISPLAY DEVICE PROVIDED WITH SAME, AND METHOD FOR PRODUCING THIN FILM TRANSISTOR SUBSTRATE

(71) Applicant: Sharp Kabushiki Kaisha, Sakai City, Osaka (JP)

(72) Inventor: Katsunori MISAKI, Yonago-shi (JP)

(21) Appl. No.: 16/634,386

(22) PCT Filed: Jul. 25, 2018
(86) PCT No.: PCT/JP2018/027789

§ 371 Date: Jan. 27, 2020

(30) Foreign Application Priority Data
Aug. 1, 2017 (JP) 2017-149265

(51) Int. Cl. H01L 29/45; H01L 27/12; H01L 29/24; H01L 29/786; H01L 29/66; G02F 1/1368

(52) U.S. Cl. CPC H01L 29/45; H01L 27/1225; H01L 29/24; G02F 1/1368; H01L 27/127; H01L 27/1288; H01L 29/66969; H01L 29/7869

(57) ABSTRACT

The present invention provides a thin-film transistor substrate with which the yield can be improved and which can reduce the resistances of electrodes, a liquid crystal display device including the thin-film transistor substrate, and a method for producing the thin-film transistor substrate. The thin-film transistor substrate of the present invention includes a base substrate, a thin-film transistor including a source electrode and a drain electrode, and a protective insulating film containing silicon oxide covering the thin-film transistor, wherein the source electrode and the drain electrode each include a laminate of an aluminum layer and a molybdenum nitride layer stacked in the stated order, and a titanium nitride/titanium layer covering the laminate.

### TECHNICAL FIELD

The present invention relates to thin-film transistor (hereinafter, also referred to as TFT) substrates, liquid crystal display devices including the TFT substrate, and methods for producing TFT substrates. The present invention specifically relates to a TFT substrate and a liquid crystal display device which include a TFT that includes a semiconductor layer containing an oxide semiconductor, and a method for producing the TFT substrate.

### BACKGROUND ART

In the field of TFT substrates constituting liquid crystal display devices, TFTs having good properties such as high carrier mobility, high reliability, and low off-current have been proposed recently. Such a TFT achieves the good properties by including a semiconductor layer that contains an oxide semiconductor (hereinafter, also referred to as oxide semiconductor layer) as a switching element of a pixel, a minimum unit of an image, differently from conventional TFTs which include semiconductor layers containing amorphous silicon.

A general bottom gate-type TFT includes, for example, a gate electrode provided on a glass substrate, a gate insulating layer covering the gate electrode, a semiconductor layer provided on the gate insulating film so as to overlap the gate electrode, a source electrode and a drain electrode which are provided on the gate insulating layer so as to overlap the semiconductor layer and are separated from each other, and a channel region at a part where the semiconductor layer is exposed between the source electrode and the drain electrode.

A known example of the bottom gate-type TFT including an oxide semiconductor layer is a channel etch-type TFT. A channel etch-type TFT is superior to an etching stopper-type TFT which includes a channel protective film serving as an etching stopper in terms of production cost because no photomask for the channel protective film is necessary. Patent Literature 1 discloses a channel etch-type TFT including an oxide semiconductor layer. The TFT includes a source electrode and a drain electrode which are produced by forming a laminate including a titanium layer formed by dry etching, a molybdenum nitride layer, an aluminum layer, and a molybdenum nitride layer stacked in the state order. The oxide semiconductor layer is formed by anneal treatment in an oxygen-containing atmosphere after forming the source electrode and the drain electrode.

### CITATION LIST

### Patent Literature

Patent Literature 1: WO 2011/155125

### SUMMARY OF INVENTION

### Technical Problem

The oxide semiconductor layer easily dissolves in an acid etchant which is generally used for wet etching source and drain electrodes. Thus, the source and drain electrodes in a channel etch-type TFT including the oxide semiconductor layer are patterned by dry etching.

In this case, however, a channel region of the oxide semiconductor layer appearing from the source and drain electrodes is exposed to plasma, so that the channel region is damaged by the plasma due to elimination of oxygen from the oxide semiconductor layer by plasma heat. Thus, in the oxide semiconductor layer, oxygen deficiency occurs to cause lattice defects, thereby increasing the threshold voltage. Consequently, the properties of the TFT are reduced in spite of the oxide semiconductor layer.

One possible solution may be performing annealing in the atmosphere to repair the lattice defects in the oxide semiconductor layer after forming the source and drain electrodes, thereby stabilizing the properties of the oxide semiconductor layer.

However, in the case of a source electrode and a drain electrode each having, for example, a stacked structure (Mo, MoN or Mo alloy)/(Al or Cu)/(Mo, MoN or Mo alloy) including: a molybdenum layer, a molybdenum nitride layer or a molybdenum alloy layer primarily containing molybdenum; a low resistant layer such as an aluminum or copper layer; and a molybdenum layer, a molybdenum nitride layer, or a molybdenum alloy layer primarily containing molybdenum, when annealing is performed after forming a protective insulating film containing silicon oxide on the source electrode and the drain electrode, a redox reaction occurs between the molybdenum-containing upper layer and the silicon oxide layer, so that the upper interface is oxidized. As a result, the protective insulating film reduces its adhesion and then delaminates during subsequent steps, thereby reducing the yield.

In the case of a source electrode and a drain electrode each having, for example, a stacked structure (Ti/(Al or Cu)/Ti) including a titanium layer, an aluminum layer or copper layer, and a titanium layer, the annealing causes mutual diffusion of particles in the aluminum layer and particles in the titanium layer. Thus, the source and drain electrodes and wires formed in the same layer are caused to have an increased resistance. As a result, due to delay of source signals, display unevenness or the like occurs in liquid crystal display devices, reducing the display quality.

The channel etch-type TFT in Patent Literature 1 includes a molybdenum-containing layer such as a molybdenum nitride layer on an aluminum layer. In such a TFT, delamination of a protective insulating film may occur as well.

An etching stopper-type TFT including an oxide semiconductor is provided with an etching stopper layer serving as a channel-protecting film. Thus, damage by plasma can be prevented at the channel region. In order to repair lattice defects due to oxygen deficiency, which are potentially exist in the oxide semiconductor layer, annealing may be performed after forming a protective insulating film containing silicon oxide on a source electrode and a drain electrode. In this case, like channel etch-type TFTs, a reduction in the yield due to delamination of the protective insulating layer and a decrease in the display quality due to an increase in the resistances of the electrodes and wires may occur.

The present invention has been made under the current situation in the art and aims to provide a thin-film transistor substrate with which the yield can be improved and which can reduce the resistances of electrodes, a liquid crystal display device including the thin-film transistor substrate, and a method for producing a thin-film transistor substrate.

### Solution to Problem

One aspect of the present invention may relate to a thin-film transistor substrate, including

a base substrate,

a thin-film transistor including: a gate electrode provided on the base substrate; a gate insulating film covering the gate electrode; a semiconductor layer containing an oxide semiconductor and provided on the gate insulating film so as to overlap the gate electrode; and a source electrode and a drain electrode which are provided so that a part of the source electrode and a part of the drain electrode are connected to the semiconductor layer and so as to face each other on the semiconductor layer, and

a protective insulating film containing silicon oxide covering the thin-film transistor,

wherein the source electrode and the drain electrode each include a laminate of a first conductive layer and a second conductive layer stacked in the stated order and a third conductive layer covering the laminate,

each first conductive layer contains a low resistance metal including at least one element selected from aluminum, copper, and silver,

each second conductive layer contains a refractory metal including a Group 5 or Group 6 metal element, an alloy primarily containing the metal element, or a nitride or oxide thereof, the refractory metal being less likely to allow metal particles of the first conductive layer to diffuse than the third layer, and

each third conductive layer directly contacts the protective insulating film and contains a refractory metal including a Group 4 metal element, an alloy primarily containing the metal element, or a nitride or oxide thereof, the refractory metal being less likely to cause a redox reaction with silicon oxide than the second conductive layer.

Another aspect of the present invention may relate to a liquid crystal display device, including:

the thin-film transistor substrate of the above-described aspect of the present invention;

a counter substrate facing the thin-film transistor substrate of the aspect of the present invention; and

a liquid crystal layer disposed between the thin-film transistor substrate of the aspect of the present invention and the counter substrate.

Another aspect of the present invention may relate to a method for producing a thin-film transistor substrate, including:

first patterning including forming a conductive film on a base substrate and patterning the conductive film using a first photomask to form a gate electrode; forming a gate insulating film so as to cover the gate electrode;

second patterning including forming a semiconductor film from an oxide semiconductor on the gate insulating film and patterning the semiconductor film using a second photomask to form a semiconductor layer;

third patterning including forming a first conductive film containing a low resistance metal including at least one element selected from aluminum, copper, and silver and a second conductive film containing a refractory metal including a Group 5 or Group 6 metal element, an alloy primarily containing the metal element, or a nitride or oxide thereof in the stated order so as to cover the semiconductor layer, and patterning the first conductive film and the second conductive film by wet etching using a third photomask;

fourth patterning including, after patterning the first conductive film and the second conductive film, forming a third conductive film containing a refractory metal including a Group 4 metal element, an alloy primarily containing the metal element, or a nitride or oxide thereof and patterning the third conductive film by dry etching to form a source electrode and a drain electrode;

protective insulating film formation including forming a protective insulating film containing silicon oxide so as to cover the source electrode and the drain electrode; and

anneal treatment including annealing the substrate with the protective insulating film.

### Advantageous Effects of Invention

The present invention can materialize a thin-film transistor substrate with which the yield can be improved and which can reduce the resistances of electrodes, and a method for producing the thin-film transistor substrate. Application of the thin-film transistor substrate in liquid crystal display devices can suppress a decrease in the display quality, while reducing the production cost of the devices.

### BRIEF DESCRIPTION OF DRAWINGS

FIG. 1 is a plan view schematically showing a liquid crystal display device of Embodiment 1.

FIG. 2 is a cross-sectional view showing a cross-sectional structure in FIG. 1 taken along the line II-II.

FIG. 3 is a plan view schematically showing the structures of one pixel and ends of lines of a TFT substrate of Embodiment 1.

FIG. 4 includes cross-sectional views showing the cross-sectional structures taken along the line A-A and the line B-B in FIG. 3.

FIG. 5 includes cross-sectional views of the regions shown in FIG. 4, each showing a state where a gate electrode is formed in first patterning in production of the TFT substrate of Embodiment 1.

FIG. 6 includes cross-sectional views of the regions shown in FIG. 4, each showing a state where a gate insulating film is formed in gate insulating film formation in production of the TFT substrate of Embodiment 1.

FIG. 7 includes cross-sectional views of the regions shown in FIG. 4, each showing a state where an oxide semiconductor layer is formed in second patterning in production of the TFT substrate of Embodiment 1.

FIG. 8 includes cross-sectional views of the regions shown in FIG. 4, each showing a state where a laminated conductive film including a titanium film, a molybdenum nitride film, an aluminum film, and a molybdenum nitride film is formed in third patterning in production of the TFT substrate of Embodiment 1.

FIG. 9 includes cross-sectional views of the regions shown in FIG. 4, each showing a state where a molybdenum nitride film, an aluminum film, and a molybdenum nitride film are patterned in third patterning in production of the TFT substrate of Embodiment 1.

FIG. 10 includes cross-sectional views of the regions shown in FIG. 4, each showing a state where a laminated conductive film including a titanium film and a titanium nitride film is formed in fourth patterning in production of the TFT substrate of Embodiment 1.

FIG. 11 includes cross-sectional views of the regions shown in FIG. 4, each showing a state where a source electrode and a drain electrode are formed by patterning a titanium film and a laminated conductive film including a titanium film and a titanium nitride film in fourth patterning in production of the TFT substrate of Embodiment 1.

FIG. 12 includes cross-sectional views of the regions shown in FIG. 4, each showing a state where a protective insulating film containing silicon oxide is formed in fifth patterning in production of the TFT substrate of Embodiment 1.

FIG. 13 includes cross-sectional views of the regions shown in FIG. 4, each showing a state where a protective insulating film containing a transparent insulating resin is formed in the fifth patterning in production of the TFT substrate of Embodiment 1.

FIG. 14 includes cross-sectional views of the regions shown in FIG. 4, each showing a state where a contact hole is formed in the gate insulating film and in the protective insulating film containing silicon oxide in the fifth patterning in production of the TFT substrate of Embodiment 1.

FIG. 15 includes cross-sectional views of the regions shown in FIG. 4, each showing a state where a common electrode is formed in sixth patterning in production of the TFT substrate of Embodiment 1.

FIG. 16 includes cross-sectional views of the regions shown in FIG. 4, each showing a state where a protective insulating film formed of a silicon oxide film or a silicon nitride film is formed in seventh patterning in production of the TFT substrate of Embodiment 1.

FIG. 17 is a plan view schematically showing the structures of one pixel and ends of lines of a TFT substrate of Embodiment 2.

FIG. 18 includes cross-sectional views showing the cross-sectional structures taken along the line A-A and the line B-B in FIG. 17.

FIG. 19 includes cross-sectional views of the regions shown in FIG. 18, each showing a state where a laminated conductive film including a molybdenum nitride film, an aluminum film, and a molybdenum nitride film is formed in third patterning in production of the TFT substrate of Embodiment 2.

FIG. 20 includes cross-sectional views of the regions shown in FIG. 18, each showing a state where a molybdenum nitride film, an aluminum film, and a molybdenum nitride film are patterned in third patterning in production of the TFT substrate of Embodiment 2.

FIG. 21 includes cross-sectional views of the regions shown in FIG. 18, each showing a state where a laminated conductive film including a titanium film and a titanium nitride film is formed in fourth patterning in production of the TFT substrate of Embodiment 2.

FIG. 22 includes cross-sectional views of the regions shown in FIG. 18, each showing a state where a source electrode and a drain electrode are formed by patterning a laminated conductive film including a titanium film and a titanium nitride film in fourth patterning in production of the TFT substrate of Embodiment 2.

FIG. 23 is a plan view schematically showing the structures of one pixel and ends of lines of a TFT substrate of Embodiment 3.

FIG. 24 includes cross-sectional views showing the cross-sectional structures taken along the line A-A and the line B-B in FIG. 23.

FIG. 25 includes cross-sectional views of the regions shown in FIG. 24, each showing a state where an etching stopper layer is formed in third patterning in production of the TFT substrate of Embodiment 3.

FIG. 26 includes cross-sectional views of the regions shown in FIG. 24, each showing a state where a contact hole is formed in the etching stopper layer in third patterning in production of the TFT substrate of Embodiment 3.

FIG. 27 is a plan view schematically showing the structures of one pixel and ends of lines of a TFT substrate of Embodiment 4.

FIG. 28 includes cross-sectional views showing the cross-sectional structures taken along the line A-A and the line B-B in FIG. 27.

### DESCRIPTION OF EMBODIMENTS

Embodiments of the present invention are described below. The embodiments, however, are not intended to limit the scope of the present invention, and modifications can be appropriately made to the design within the scope of the present invention.

### Embodiment 1

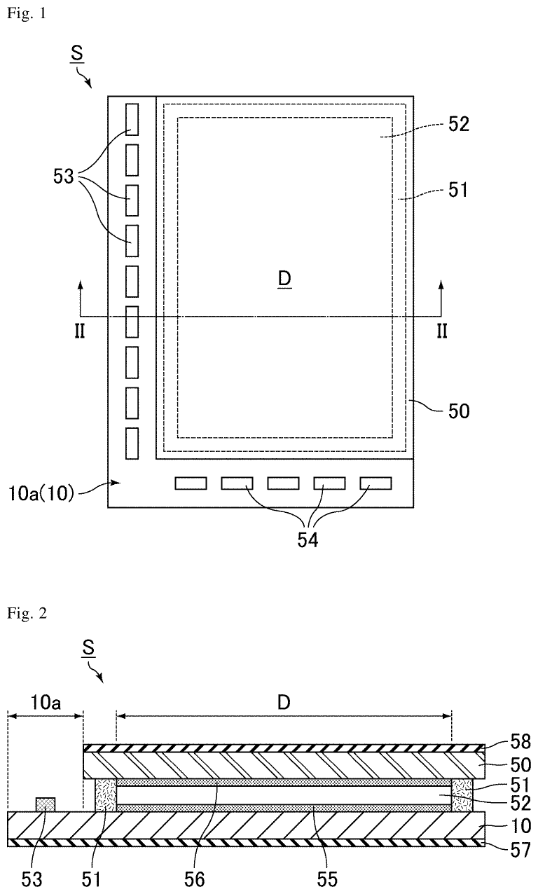

FIG. 1 is a schematic plan view of a liquid crystal display device S of this embodiment. FIG. 2 is a cross-sectional view showing a cross-sectional structure taken along the line II-II in FIG. 1. FIG. 1 does not show a polarizing plate 58 shown in FIG. 2.

### <Structure of Liquid Crystal Display Device S>

The liquid crystal display device S includes a TFT substrate 10 and a counter substrate 50 facing each other, a sealant 51 in a frame pattern which bonds the TFT substrate 10 and the counter substrate 50 at their outer edges, and a liquid crystal layer 52 enclosed inside the sealant 51 between the TFT substrate 10 and the counter substrate 50.

The liquid crystal display device S is a transmissive liquid crystal display device and includes a display region D for image display in a region where the TFT substrate 10 and the counter substrate 50 overlap each other inside the sealant 51, i.e., a region where the liquid crystal layer 52 is disposed. Outside the display region D is provided a terminal region 10a which is, for example, an L-shaped part of the TFT substrate 10 protruding from the counter substrate 50.

The display region D has a rectangle shape, for example, and includes pixels, which are minimum units of an image, arranged in a matrix. On one side (left side in FIG. 1) of the terminal region 10a, gate driver integrated circuit (hereinafter, abbreviated to IC) chips 53 are mounted via anisotropic conductive films (hereinafter, abbreviated to ACFs). On another side (bottom side in FIG. 1) of the terminal region 10a, source driver IC chips 54 are mounted via ACFs.

The TFT substrate 10 and the counter substrate 50 each have a rectangle shape, for example, and as shown in FIG. 2, respectively have alignment films 55 and 56 on their facing inner surfaces and respectively have polarizing plates 57 and 58 on their outer surfaces. The liquid crystal layer 52 contains a nematic liquid crystal material having electro-optical properties, for example.

### <Structure of TFT Substrate 10>

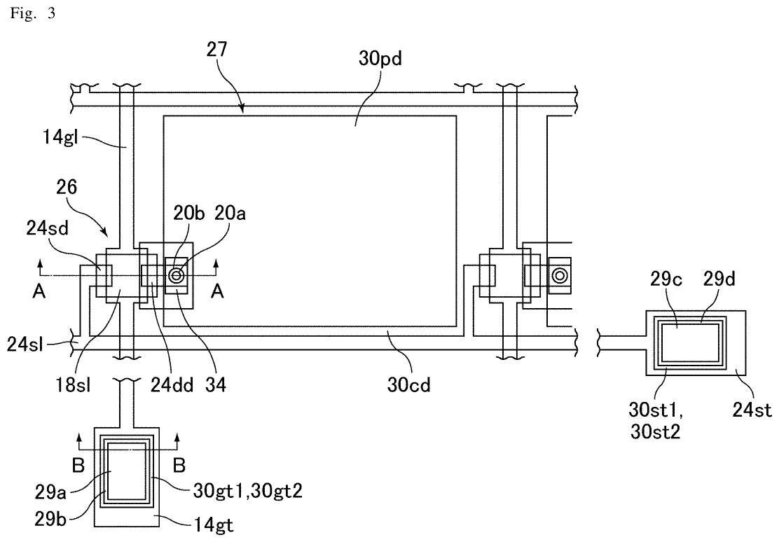

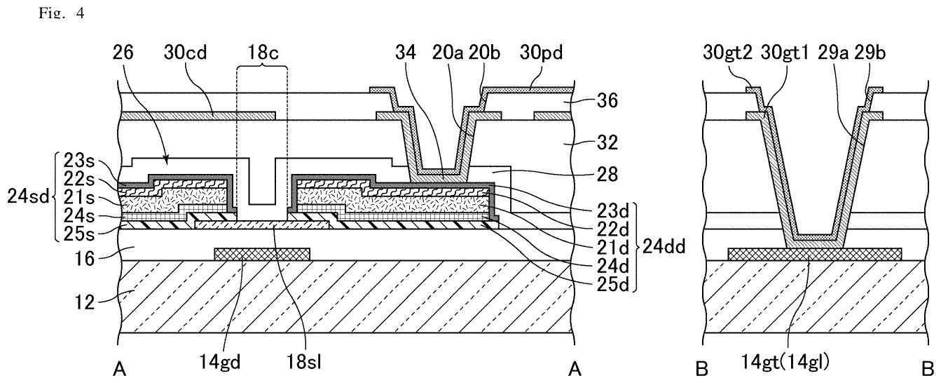

FIG. 3 and FIG. 4 illustrate schematic structures of the TFT substrate 10. FIG. 3 is a plan view showing one pixel and ends of lines. FIG. 4 includes cross-sectional views showing the cross-sectional structures taken along the line A-A and the line B-B in this order from left in FIG. 3.

As shown in FIG. 4, the TFT substrate 10 includes an insulating substrate 12 such as a glass substrate serving as a base substrate. As shown in FIG. 3, in the display region D, the insulating substrate 12 has parallel gate lines 14gl and parallel source lines 24sl that intersect the gate lines 14gl with an insulating film in between. The gate lines 14gl and the source lines 24sl form a grid pattern to partition the pixels.

The TFT substrate 10 further includes, in each intersection of the gate lines 14gl and the source lines 24sl, i.e., in each pixel, a TFT 26, a storage capacitor element 27, and a pixel electrode 30pd. The TFT substrate 10 also includes a common electrode 30cd provided in common in all the pixels.

The TFT 26 is a channel etch-type TFT. As shown in FIG. 4 (the cross section taken along the line A-A), each TFT 26 includes: a gate electrode 14gd provided on the insulating substrate 12; a gate insulating film 16 covering the gate electrode 14gd; an oxide semiconductor layer 18sl provided on the gate insulating film 16 so as to overlap the gate electrode 14gd; and a source electrode 24sd and a drain electrode 24dd which are provided on the gate insulating film 16 so that a part of the source electrode 24sd and a part of the drain electrode 24dd are connected to the oxide semiconductor layer 18sl and so as to face each other on the oxide semiconductor layer 18sl. A channel region 18c is formed in a part of the oxide semiconductor layer 18sl which is located between the source electrode 24sd and the drain electrode 24dd. The source electrode 24sd is connected to a branch of the corresponding source line 24sl.

The gate electrode 14gd is a part of the gate line 14gl that constitutes the corresponding intersection and includes protrusions extending from both sides of the gate line 14gl in the width direction as shown in FIG. 3. The channel length of the TFT 26 is controlled by adjusting the width of each protrusion. Although not shown, the gate electrode 14gd has a structure in which the gate line 14gl, an aluminum (Al) layer, and a molybdenum (Mo) layer, for example, are stacked in the stated order and integrated.

The gate insulating film 16 includes, for example, silicon nitride (SiN), silicon oxide (SiO₂), or a laminated film in which a silicon nitride film and a silicon oxide film are stacked in the stated order and integrated. The oxide semiconductor layer 18sl includes an indium-gallium-zinc oxide (hereinafter, abbreviated to In-Ga—Zn-O) semiconductor.

The source electrode 24sd and the drain electrode 24dd each include: a laminate including a molybdenum nitride (MoN) layer 24s or 24d as a fourth conductive layer, an aluminum (Al) layer 21s or 21d as a first conductive layer, and a molybdenum nitride (MoN) layer 22s or 22d as a second conductive layer which are stacked in the stated order; and a titanium (Ti) layer 25s or 25d as a fifth conductive layer and a titanium nitride (TiN)/titanium (Ti) layer 23s or 23d as a third conductive layer which vertically sandwich the laminate. The titanium layers 25s and 25d each overlap the entirety of the corresponding laminate. The titanium nitride/titanium layers 23s and 23d each cover the upper face and side faces of the corresponding laminate. Thus, each laminate is completely covered by the titanium layer 25s or 25d and the titanium nitride/titanium layer 23s or 23d. The aluminum layers 21s and 21d tend to cause a redox reaction with the oxide semiconductor and silicon oxide. The titanium layers 25s and 25d and titanium nitride/titanium layers 23s and 23d are less likely to cause a redox reaction with the oxide semiconductor and silicon oxide than the aluminum layers 21s and 21d, and are less likely to cause a redox reaction with silicon oxide than the molybdenum nitride layers 22s, 22d, 24s, and 24d. Metal particles of the aluminum layers 21s and 21d are less likely to diffuse into the molybdenum nitride layers 22s, 22d, 23s, and 24d than into the titanium layers 25s and 25d and titanium nitride/titanium layers 23s and 23d.

As described in detail below, the titanium layers 25s and 25d and titanium nitride/titanium layers 23s and 23d are formed by patterning a titanium film, a titanium nitride film, and a titanium film, which are formed as solid films on the entire substrate, by dry etching. The molybdenum nitride layers 24s and 24d, the aluminum layers 21s and 21d, and the molybdenum nitride layers 22s and 22d are formed by patterning a laminated film of a molybdenum nitride film, an aluminum film, and a molybdenum nitride film, which is formed as a solid film on the entire substrate, by wet etching.

As shown in FIG. 4, each TFT 26 is covered with a silicon oxide (SiO₂)-based protective insulating film 28 and a protective insulating film 32 containing a transparent insulating resin. The protective insulating film 28 that contains silicon oxide can prevent the oxide semiconductor layer 18sl from having oxygen deficiency, which may be caused by hydrogen desorption in the film when the protective insulating film 28 contains a different substance such as silicon nitride. A common electrode 30cd and a connection electrode 34 are provided on the protective insulating film 32. The common electrode 30cd and the connection electrode 34 are covered with a protective insulating film 36 containing silicon nitride (SiN) or silicon oxide (SiO₂). Each pixel electrode 30pd is provided on the protective insulating film 36.

The common electrode 30cd and each pixel electrode 30pd each contain an indium tin oxide (hereinafter, referred to as ITO) or an indium zinc oxide (hereinafter, referred to as IZO). The common electrode 30cd is formed on the substantially entire display region D, and each pixel electrode 30pd is formed on the substantially entire pixel. The pixel electrode 30pd is provided with slits (not shown). The protective insulating films 28 and 32 each include a contact hole 20a and the protective insulating film 36 includes a contact hole 20b. The contact holes 20a and 20b are each formed in the region corresponding to and reaching the drain electrode 24dd in each pixel. The connection electrode 34 is formed in an island shape so as to overlap the contact hole 20a in each pixel. The pixel electrode 30pd is connected to the drain electrode 24dd via the connection electrode 34 through the contact holes 20a and 20b in each pixel.

The storage capacitor element 27 includes a pixel electrode 30pd, a dielectric layer that is a protective insulating film in a region corresponding to the pixel electrode 30pd, and a common electrode in a region corresponding to the pixel electrode 30pd via the dielectric layer.

Each gate line 14gl extends to the terminal region 10a on which the gate driver IC chips 53 are mounted, and the lead-out end of each gate line 14gl constitutes a gate terminal 14gt shown in FIG. 3. The gate terminal 14gt is connected to a gate connection electrode 30gt1 disposed on the protective insulating film 32 and to a gate connection electrode 30gt2 disposed on the protective insulating film 36 through a contact hole 29a shown in FIG. 4 (the cross section taken along the line B-B), which is formed in the gate insulating film 16 and the protective insulating films 28 and 32, and a contact hole 29b shown in FIG. 4 (the cross section taken along the line B-B), which is formed in the protective insulating film 36. The gate connection electrodes 30gt1 and 30gt2 are electrically connected to the gate driver IC chip 53.

Each source line 24sl extends to the terminal region 10a on which the source driver IC chips 54 are mounted, and the lead-out end of each source line 24sl constitutes a source terminal 24st shown in FIG. 3. The source terminal 24st is connected to a source connection electrode 30st1 disposed on the protective insulating film 32 and a source connection electrode 30st2 disposed on the protective insulating film 36 through a contact hole 29c formed in the protective insulating films 28 and 32 and a contact hole 29d formed in the protective insulating film 36. The source connection electrodes 30st1 and 30st2 are electrically connected to the source driver IC chip 54.

The ends of the common electrode 30cd reach the regions with the sealant 51 and are connected to common lines (not shown). Common voltage is applied to the common electrode 30cd via the common lines.

### <Structure of Counter Substrate 50>

Although not shown, the counter substrate 50 includes a black matrix on an insulating substrate as a base substrate in a grid pattern that corresponds to the gate lines 14gl and the source lines 24sl; color filters with multiple colors including a red layer, a green layer, and a blue layer that are periodically arranged in the grid rectangles of the black matrix; an overcoat layer that is formed from a transparent insulating resin and covers the black matrix and the color filters; and columnar photo spacers disposed on the overcoat layer.

### <Operation of Liquid Crystal Display Device S>

In each pixel of the liquid crystal display device S having the above structure, a gate signal is sent from the gate driver IC chip 53 to the gate electrode 14gd via the gate line 14gl, whereby the TFT 26 is turned on. Then, a source signal is sent from the source driver IC chip 54 to the source electrode 24sd via the source line 24sl, whereby a predetermined charge is written in the pixel electrode 30pd while the storage capacitor element 27 is charged via the oxide semiconductor layer 18sl and the drain electrode 24dd. Here, a potential difference is caused between the pixel electrode 30pd and the common electrode 30cd, whereby a predetermined voltage is applied to the liquid crystal layer 52. When the TFT 26 is turned off, the storage capacitance formed in the storage capacitor element 27 holds the voltage written in the pixel electrode 30pd so as not to be reduced. In each pixel of the liquid crystal display device S, the alignment of liquid crystal molecules is changed according to the magnitude of the voltage applied to the liquid crystal layer 52 to control the light transmittance of the liquid crystal layer 52, whereby an image is displayed.

### —Production Method—

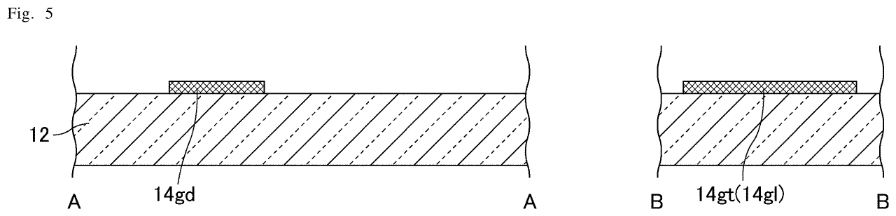

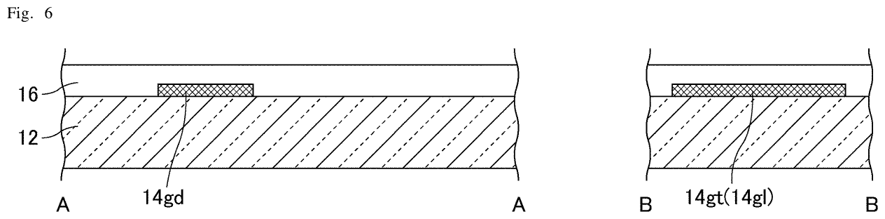

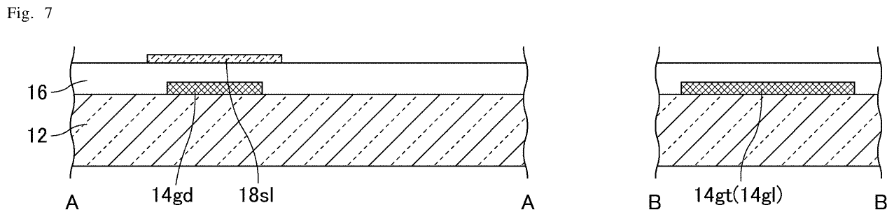

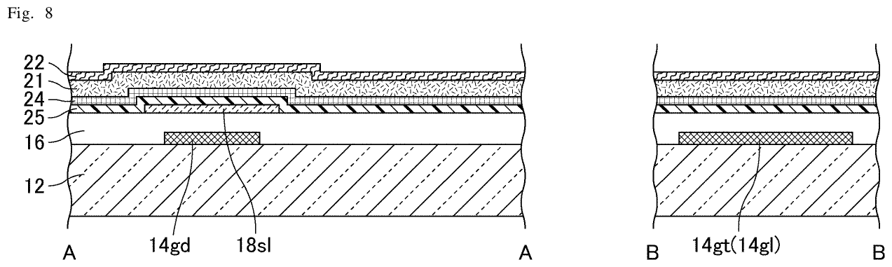

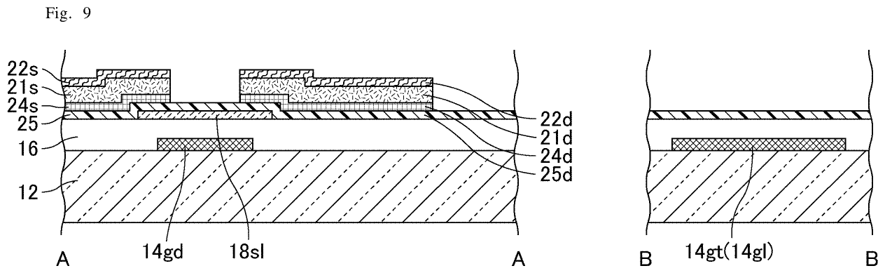

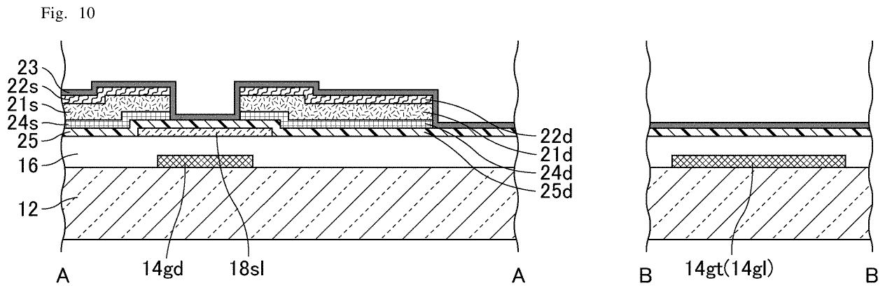

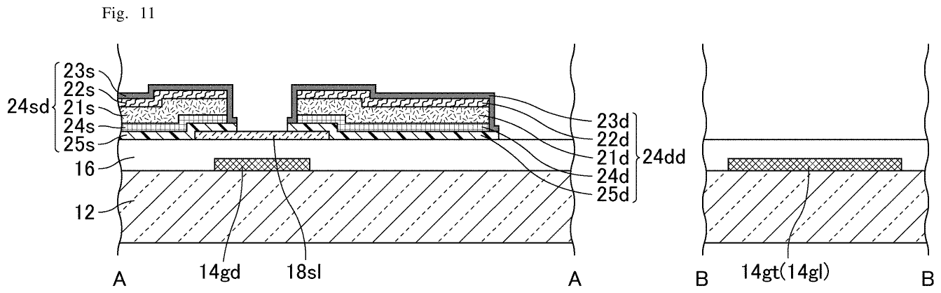

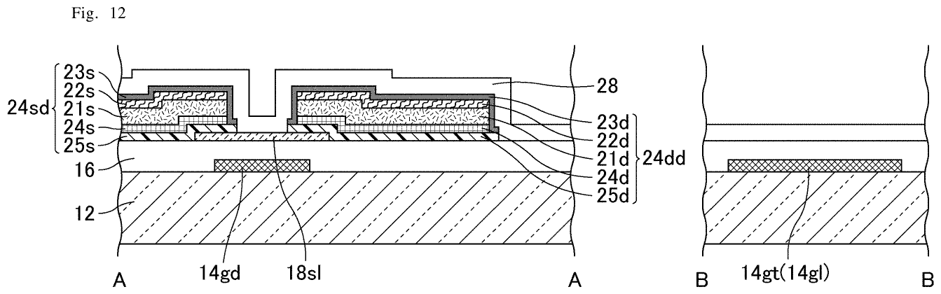

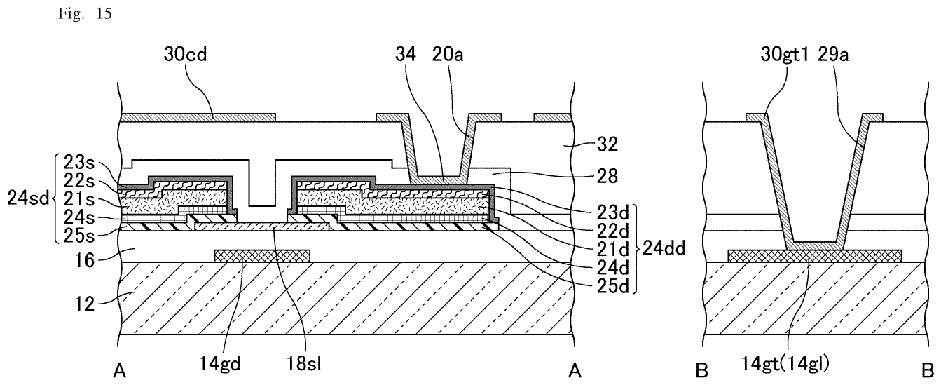

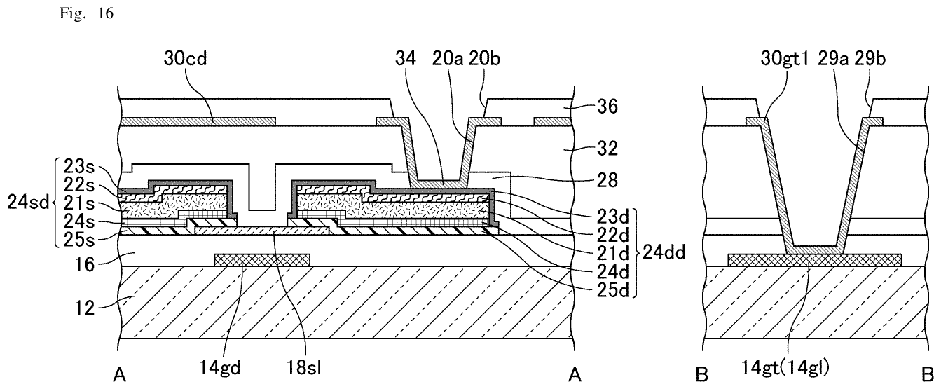

An example of a method for producing the TFT substrate 10 and the liquid crystal display device S will be described below with reference to FIGS. 5 to 16. FIGS. 5 to 16 are cross-sectional of the regions shown in FIG. 4, where FIG. 5 shows first patterning in the production method of the TFT substrate 10, FIG. 6 shows gate insulating film formation in the production method of the TFT substrate 10, FIG. 7 shows second patterning in the production method of the TFT substrate 10, FIGS. 8 and 9 show third patterning in the production method of the TFT substrate 10, FIGS. 10 and 11 show fourth patterning in the production method of the TFT substrate 10, FIGS. 12 to 14 show fifth patterning in the production method of the TFT substrate 10, FIG. 15 shows sixth patterning in the production method of the TFT substrate 10, and FIG. 16 shows seventh patterning in the production method of the TFT substrate 10.

The method for producing the liquid crystal display device S of the present embodiment includes production of a TFT substrate, production of a counter substrate, attaching, and mounting.

### <Production of TFT Substrate>

The production of the TFT substrate includes first patterning to eighth patterning.

### <First Patterning>

The insulating substrate 12 such as a glass substrate is prepared in advance. Then, films such as an aluminum film (thickness: for example, about 200 nm) and a molybdenum film (thickness: for example, about 100 nm) are stacked in the stated order by sputtering to form a laminated conductive film. Then, a resist pattern is formed on the laminated conductive film in the regions for forming a gate line 14gl, a gate electrode 14gd, and a gate terminal 14gt by photolithography using a first photomask. Using the resist pattern as a mask, the laminated conductive film is patterned by reactive ion etching (hereinafter, abbreviated to RIE). The RIE is a kind of dry etching and uses a chlorine-based gas. The resist pattern is removed with a resist stripper and the workpiece is washed. Accordingly, the gate line 14gl, the gate electrode 14gd, and the gate terminal 14gt are simultaneously formed as shown in FIG. 5.

### <Gate Insulating Film Formation>

On the substrate with components such as the gate electrode 14gd and the gate terminal 14gt are formed a silicon nitride film (thickness: for example, about 350 nm) and a silicon oxide film (thickness: for example, about 50 nm) in the stated order by CVD to form the gate insulating film 16 as shown in FIG. 6.

### <Second Patterning>

A semiconductor film (thickness: for example, about 70 nm) including an In—Ga—Zn—O-based oxide semiconductor is formed by sputtering on the substrate with the gate insulating film 16. Then, a resist pattern is formed on the semiconductor film by photolithography using a second photomask. Thereafter, using the resist pattern as a mask, the semiconductor film is patterned by wet etching with an oxalic acid liquid. Subsequently, the resist pattern is removed with a resist stripper and the workpiece is washed. Accordingly, the oxide semiconductor layer 18sl is formed as shown in FIG. 7.

### <Third Patterning>

A titanium film 25 (thickness: 100 nm or less, e.g., about 30 nm), a molybdenum nitride film 24 (thickness: for example, about 50 nm), an aluminum film 21 (thickness: for example, about 300 nm), and a molybdenum nitride film 22 (thickness: for example, about 100 nm) are formed in the stated order by sputtering on the substrate with the oxide semiconductor layer 18sl. Accordingly, a laminated conductive film is formed as shown in FIG. 8.

Then, a resist pattern is formed on the laminated conductive film in the regions for forming the source line 24sl, the source electrode 24sd, the drain electrode 24dd, and the source terminal 24st by photolithography using a third photomask.

Next, the upper three layers of the laminated conductive film, namely the molybdenum nitride film 24, the aluminum film 21, and the molybdenum nitride film 22, are patterned using the resist pattern as a mask by wet etching, for example, at 40° C. for 60 seconds with a mixture of phosphoric acid, acetic acid, and nitric acid. Thus, the molybdenum nitride layers 24s and 24d, the aluminum layers 21s and 21d, and the molybdenum nitride layers 22s and 22d which constitute the source line 24sl, the source electrode 24sd, the drain electrode 24dd, and the source terminal 24st are formed as shown in FIG. 9.

### <Fourth Patterning>

Thereafter, a titanium film (thickness: for example, about 30 nm) and a titanium nitride film (thickness: for example, about 5 nm) are formed in the stated order by sputtering on the substrate with the molybdenum nitride layers 24s and 24d, the aluminum layers 21s and 21d, and the molybdenum nitride layers 22s and 22d. Accordingly, a laminated conductive film 23 (thickness: 100 nm or less) is formed as shown in FIG. 10.

Then, a resist pattern is formed on the laminated conductive film 23 in the regions for forming the source line 24sl, the source electrode 24sd, the drain electrode 24dd, and the source terminal 24st by photolithography using a fourth photomask. The photoresist pattern may be formed using the third photomask. In this case, the number of the photomasks can be reduced, and the production cost can be reduced.

Next, the titanium film 25 and the laminated conductive film 23 are patterned using the resist pattern together with the previously-formed molybdenum nitride layers 24s and 24d, aluminum layers 21s and 21d, and molybdenum nitride layers 22s and 22m as masks by RIE. Accordingly, the source line 24sl, the source electrode 24sd, the drain electrode 24dd, and the source terminal 24st are simultaneously formed as shown in FIG. 11.

The RIE is performed using, for example, a mixed gas containing Cl₂ (flow rate: about 100 sccm) and BCl₃ (flow rate: about 100 sccm) as a raw material gas at a chamber inner pressure of about 4 Pa and at a high frequency power of about 1100 W, for example.

### <Fifth Patterning (Formation of Protective Insulating Film and Annealing)>

A silicon oxide film is formed by CVD on the substrate with components such as the source electrode 24sd, and the drain electrode 24dd to form the protective insulating film 28 (thickness: for example, about 270 nm) as shown in FIG. 12.

The substrate with the protective insulating film 28 is subjected to high temperature annealing in an annealing chamber with an oxygen-containing atmosphere at about 100° C. to 450° C. and an atmospheric pressure using oxygen gas as a carrier gas. The protective insulating film containing silicon oxide 28 generally has a higher oxygen permeability than a silicon nitride film, for example. Thus, oxygen used in the annealing is effectively supplied to the channel region 18c of the oxide semiconductor layer 18sl. Even when the channel region 18c of the oxide semiconductor layer 18sl has been exposed to plasma by CVD for forming the protective insulating film 28 and thus oxygen in the channel region 18c has been lost, the annealing after formation of the protective insulating film 28 can repair the oxygen deficiency in the oxide semiconductor layer 18sl. Thus, the properties of the semiconductor layer 18sl can be stabilized.

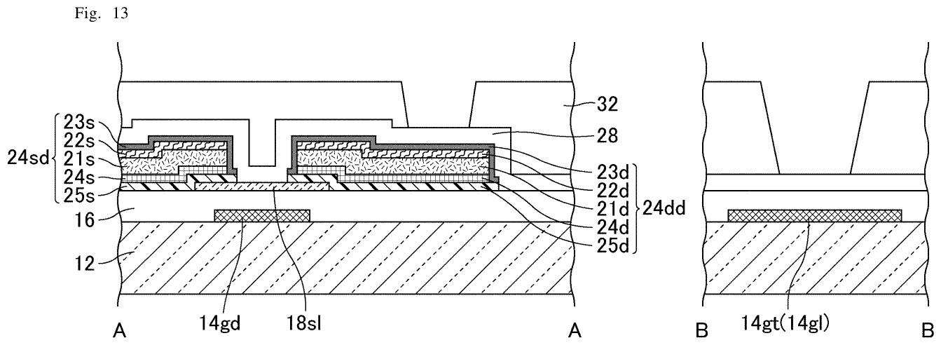

A transparent insulating resin film (thickness: for example, about 2 to 4 μm) containing a positive photosensitive acrylic transparent resin is formed by spin coating or slit coating on the annealed substrate. Then (after pre-baking), the regions for forming the contact holes 20a, 29a, and 29c and the regions to be removed are exposed to light by photolithography using a fifth photomask and developed, whereby patterning is performed. In order to make the resin transparent (bleached), the entire surface is exposed to light at an exposure dose of 280 to 350 mJ/cm² and subsequently post-baked at 200° C. to 230° C. Accordingly, the protective insulating film 32 is formed as shown in FIG. 13.

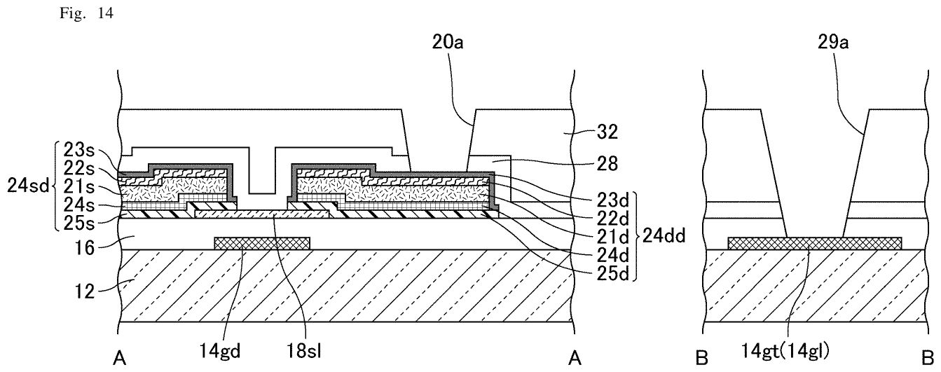

Next, a resist pattern with openings in the regions for forming the contact holes 20a, 29a, and 29c is formed by photolithography using the fifth photomask on the substrate with the protective insulating film 32. Using the resist pattern as a mask, the gate insulating film 16 and the protective insulating film 28 are patterned by RIE with a fluorine-based gas. Accordingly, the contact holes 20a, 29a, and 29c are formed as shown in FIG. 14.

### <Sixth Patterning>

On the substrate with the patterned protective insulating films 28 and 32 is formed a transparent conductive film such as an ITO film or an IZO film (thickness: for example, about 70 nm) by sputtering. Then, a resist pattern is formed on the transparent conductive film in the regions for forming the common electrode 30cd, the connection electrode 34, the gate connection electrode 30gt1, and the source connection electrode 30st1 by photolithography using a sixth photomask. Using the resist pattern as a mask, the transparent conductive film is patterned by wet etching with an oxalic acid liquid. The resist pattern is removed with a resist stripper and the workpiece is washed. Accordingly, the common electrode 30cd, the connection electrode 34, the gate connection electrode 30gt1, and the source connection electrode 30st1 are formed as shown in FIG. 15.

### <Seventh Patterning>

A silicon oxide film or a silicon nitride film is formed by CVD on the substrate with components such as the common electrode 30cd and the connection electrode 34 to form the protective insulating film 36 (thickness: for example, about 300 nm).

On the substrate with the protective insulating film 36 is formed a resist pattern with openings in the regions for forming the contact holes 20b, 29b, and 29d by photolithography using a seventh photomask. Using the resist pattern as a mask, the protective insulating film 36 is patterned by RIE with a fluorine-based gas. The resist pattern is removed with a resist stripper and the workpiece is washed. Accordingly, the contact holes 20b, 29b, and 29d are formed as shown in FIG. 16.

### <Eighth Patterning>

A transparent conductive film such as an ITO film or an IZO film (thickness: for example, about 70 nm) is formed on the substrate with the contact holes 20b, 29b, and 29d by sputtering. Then, a resist pattern is formed on the transparent conductive film in the regions for forming the pixel electrode 30pd, the gate connection electrode 30gt2, and the source connection electrode 30st2 by photolithography using an eighth photomask. Using the resist pattern as a mask, the transparent conductive film is patterned by wet etching with an oxalic acid liquid. The resist pattern is removed with a resist stripper and the workpiece is washed. Accordingly, the pixel electrode 30pd, the gate connection electrode 30gt2, and the source connection electrode 30st2 are formed.

The TFT substrate 10 shown in FIG. 4 can be produced as described above.

### <Production of Counter Substrate>

A black photosensitive resin is applied to an insulating substrate such as a glass substrate by spin coating or slit coating, for example. The coat is exposed to light through the photomask and then developed to be patterned, whereby a black matrix is formed.

A red, green, or blue negative acrylic photosensitive resin, for example, is applied to the substrate with the black matrix. The coat is exposed to light through the photomask and then developed to be patterned, whereby a color layer in the selected color (e.g., red layer) is formed. Two color layers in other two colors (e.g., green layer and blue layer) are formed in the same manner as above, whereby color filters are formed.

A transparent insulating resin film containing, for example, an acrylic transparent resin is formed on the substrate with the color filters by spin coating or slit coating, whereby an overcoat layer is formed.

A positive phenol novolac-based photosensitive resin is applied to the substrate with the overcoat layer by spin coating. The coat is exposed to light through the photomask and then developed to be patterned, whereby photo spacers are formed.

The counter substrate 50 can be produced as described above.

### <Attaching>

A polyimide-based resin is applied to a surface of the TFT substrate 10 by printing. The coat is subjected to baking and rubbing to form an alignment film 55. A polyimide-based resin is applied to a surface of the counter substrate 50 by printing. The coat is subjected to baking and rubbing to form an alignment film 56.

The sealant 51 such as an ultraviolet-curable thermosetting resin is applied in a rectangular frame pattern to the counter substrate 50 with the alignment film 56 using a tool such as a dispenser. Then, a predetermined amount of a liquid crystal material is dropped in the region inside the sealant 51 on the counter substrate 50.

The counter substrate 50 with the dropped liquid crystal material and the TFT substrate 10 with the alignment film 55 are attached together under reduced pressure. The attached workpiece is placed under atmospheric pressure to pressurize the surfaces of the attached workpiece. The sealant 51 of the attached workpiece is irradiated with ultra violet (UV) light to be pre-cured. Thereafter, the attached workpiece is heated so that the sealant 51 is post-cured, thereby attaching the TFT substrate 10 to the counter substrate. 50

Then, a polarizing plate 57 is attached to one outer surface and a polarizing plate 58 is attached to the other outer surface of the attached body of the TFT substrate 10 and the counter substrate 50.

### <Mounting>

ACFs are placed in the terminal region 10a of the attached body whose surfaces are covered with the polarizing plates 57 and 58. Then, the gate driver IC chips 53 and the source driver IC chips 54 are mounted on the ACFs in the terminal region 10a of the attached body by thermocompression bonding.

The liquid crystal display device S can be produced as described above.

In this embodiment, the titanium nitride/titanium layers 23s and 23d are less likely to cause a redox reaction with silicon oxide than the molybdenum nitride layers 22s and 22d, and also cover the molybdenum nitride layers 22s and 22d which cause a redox reaction with the protective insulating film containing silicon oxide 28. During annealing of the oxide semiconductor layer 18sl after forming the protective insulating film 28, the molybdenum nitride layers 22s and 22d are less likely to cause a redox reaction with the protective insulating film 28, so that the adhesion of the protective insulating film 28 is ensured. Thus, a reduction in the yield due to delamination of the protective insulating film 28 after the annealing can be prevented. Additionally, the metal particles of the aluminum layers 21s and 21d are less likely to diffuse into the molybdenum nitride layers 22s and 22d than into the titanium nitride/titanium layers 23s and 23d. Thus, during the annealing, the metal particles of the aluminum layers 21s and 21d are prevented from diffusing into the molybdenum nitride layers 22s and 22d. The molybdenum nitride layers 22s and 22d can prevent the metal particles of the aluminum layers 21s and 21d from diffusing into the titanium nitride/titanium layers 23s and 23d, thereby preventing an elevation in the resistances of the source electrode 24sd, drain electrode 24dd, and source line 24sl. This can increase the yield and provide a TFT substrate 10 capable of reducing the resistances of electrodes and lines. Hence, the TFT substrate 10 can be produced at a low cost by using a total of eight (preferably seven) photomasks, and at the same time a decrease in the display quality such as display unevenness of the liquid crystal display device S can be prevented.

In this embodiment, the titanium layers 25s and 25d are less likely to cause a redox reaction with the oxide semiconductor than the aluminum layers 21s and 21d. During annealing of the oxide semiconductor layer 18sl after forming the protective insulating film containing silicon oxide 28, the titanium layers are less likely to cause a redox reaction with the oxide semiconductor, and reduction and metallization of the oxide semiconductor layer 18sl by the source electrode 24sd and the drain electrode 24dd can be prevented. Thus, the annealing can satisfactorily repair lattice defects in the oxide semiconductor layer 18sl and reliably stabilize the properties, e.g., the threshold value, of the oxide semiconductor layer 18sl. The metal particles of the aluminum layers 21s and 21d are less likely to diffuse into the molybdenum nitride layers 24s and 24d than into the titanium layers 25s and 25d. Thus, during the annealing, the metal particles of the aluminum layers 21s and 21d are prevented from diffusing into the molybdenum nitride layers 24s and 24d. The molybdenum nitride layers 24s and 24d can prevent the metal particles of the aluminum layers 21s and 21d from diffusing into the titanium layers 25s and 25d, thereby preventing an elevation in the resistances of the source electrode 24sd, drain electrode 24dd, and source line 24sl. This enables production of a TFT substrate 10 capable of reducing the resistances of electrodes and lines, even in the case where the TFT substrate 10 includes the titanium layers 25s and 25d.

In this embodiment, the titanium nitride/titanium layers 23s and 23d each cover the laminate of the molybdenum nitride layer 24s or 24d, the aluminum layer 21s or 21d, and the molybdenum nitride layer 22s or 22d, which are altogether patterned, thereby allowing the source electrode 24sd and the drain electrode 24dd to maintain the good tapered shapes. A source electrode 24sd and a drain electrode 24dd each having a poor tapered shape may insufficiently cover the protective insulating film 28. In this case, for example, moisture may penetrate into the channel region 18c of the TFT 26, thereby possibly making the threshold voltage as the properties of the TFT 26 unstable. In contrast, a source electrode 24sd and a drain electrode 24dd each having a good tapered shape can almost perfectly prevent entering (penetration) of moisture during the production of the TFT substrate, or of the moisture absorbed and remaining in the protective insulating film 32. Thus, the characteristic threshold voltage of the TFT 26 can be stabilized, so that a decrease in the display quality such as display unevenness of the liquid crystal display device S can be better prevented.

### Embodiment 2

In the present embodiment, the characteristic features of the present embodiment are mainly described and the same points as in Embodiment 1 are not described. The components having the same or a similar function have the same reference numerals in both the present embodiment and Embodiment 1, and such components are not described in the present embodiment. The present embodiment is substantially the same as Embodiment 1, except that the fifth conductive layer is not present as described below.

### <Structure of TFT Substrate 10>

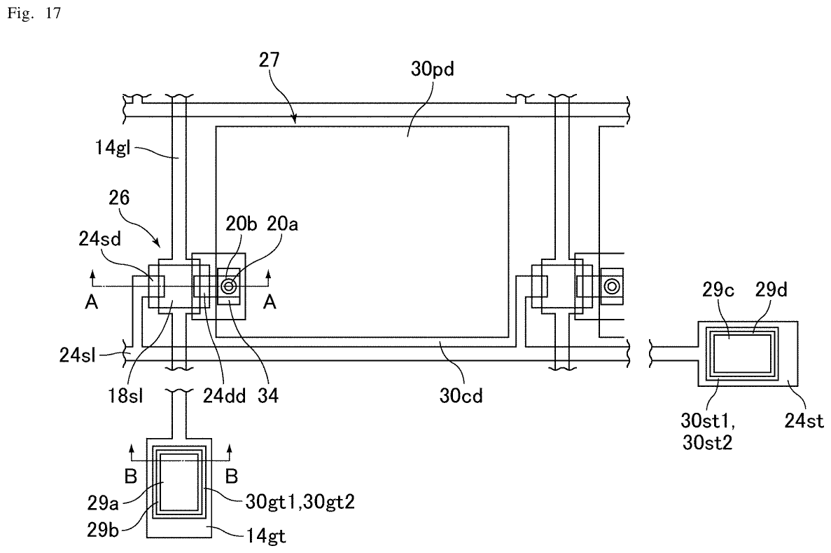

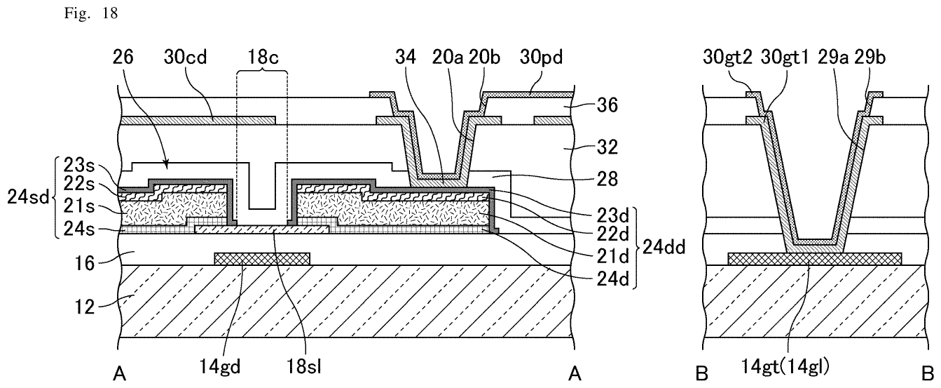

FIG. 17 and FIG. 18 illustrate schematic structures of the TFT substrate 10 according to this embodiment. FIG. 17 is a plan view showing one pixel and ends of lines. FIG. 18 is a cross-sectional view showing the cross-sectional structures taken along the line A-A and the line B-B in this order from left in FIG. 17.

As shown in FIG. 17, the TFT substrate 10 in this embodiment has a plan face layout similar to that of the TFT substrate 10 of Embodiment 1.

As shown in FIG. 18, the source electrode 24sd and the drain electrode 24dd in the TFT substrate 10 do not include the titanium layers 25s and 25d as a fifth conductive layer, and each include: a laminate including a molybdenum nitride layer 24s or 24d as a fourth conductive layer, an aluminum layer 21s or 21d as a first conductive layer, and a molybdenum nitride layer 22s or 22d as a second conductive layer stacked in the stated order; and a titanium nitride/titanium layer 23s or 23d as a third conductive layer which is provided so as to cover the laminate. The titanium nitride/titanium layers 23s and 23d cover the upper face and side faces of the laminate.

### —Production Method—

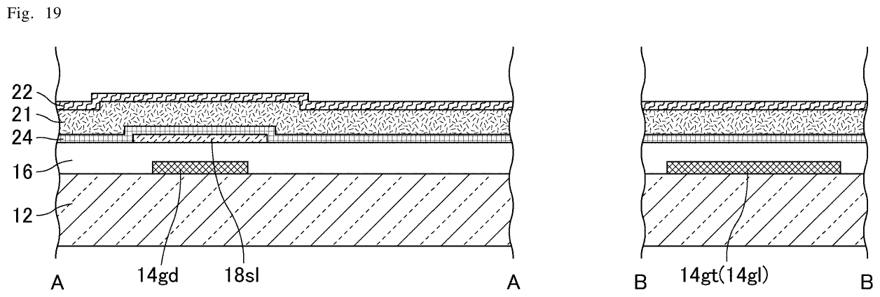

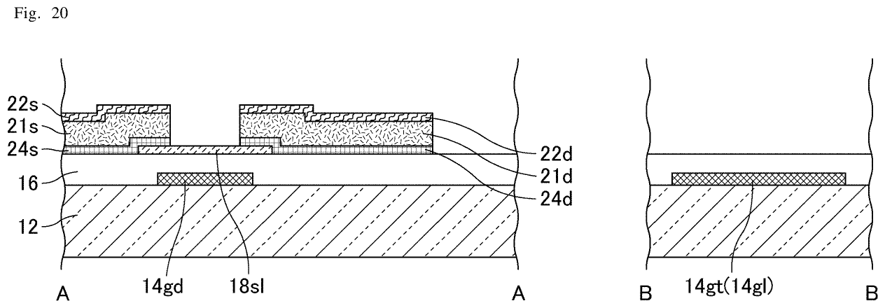

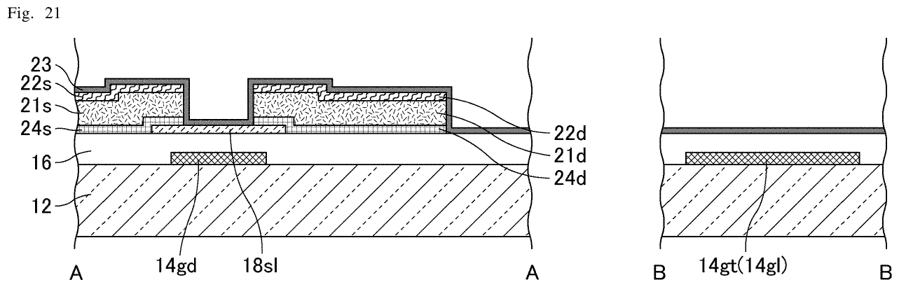

An example of a method for producing the TFT substrate 10 of this embodiment will be described below with reference to FIGS. 19 to 22. FIGS. 19 and 20 are cross-sectional views of the regions shown in FIG. 18 showing third patterning in the production method of the TFT substrate 10. FIGS. 21 and 20 are cross-sectional views of the regions shown in FIG. 18 showing fourth patterning in the production method of the TFT substrate 10.

### <Production of TFT Substrate>

The production of the TFT substrate includes first patterning to eighth patterning.

### <First and Second Patternings>

First, the first patterning and the second patterning are performed as in Embodiment 1.

### <Third Patterning>

The molybdenum nitride film 24 (thickness: for example, about 50 nm), the aluminum film 21 (thickness: for example, about 300 nm), and the molybdenum nitride film 22 (thickness: for example, about 100 nm) are formed in the stated order by sputtering on the substrate with the oxide semiconductor layer 18sl. Accordingly, a laminated conductive film is formed as shown in FIG. 19.

Then, a resist pattern is formed on the laminated conductive film in the regions for forming the source line 24sl, the source electrode 24sd, the drain electrode 24dd, and the source terminal 24st by photolithography using a third photomask.

Next, the laminated conductive film is patterned using the resist pattern as a mask by wet etching, for example, at 40° C. for 60 seconds with a mixture of phosphoric acid, acetic acid, and nitric acid. Thus, molybdenum nitride layers 24s and 24d, aluminum layers 21s and 21d, and molybdenum nitride layers 22s and 22d which constitute the source line 24sl, the source electrode 24sd, the drain electrode 24dd, and the source terminal 24st are formed as shown in FIG. 20.

### <Fourth Patterning>

Thereafter, a titanium film (thickness: for example, about 30 nm) and a titanium nitride film (thickness: for example, about 5 nm) are formed in the stated order by sputtering on the substrate with the molybdenum nitride layers 24s and 24d, the aluminum layers 21s and 21d, and the molybdenum nitride layers 22s and 22d. Accordingly, a laminated conductive film 23 (thickness: 100 nm or less) is formed as shown in FIG. 21.

Then, a resist pattern is formed on the laminated conductive film 23 in the regions for forming the source line 24sl, the source electrode 24sd, the drain electrode 24dd, and the source terminal 24st by photolithography using a fourth photomask. The photoresist pattern may be formed using the third photomask. In this case, the number of the photomasks can be reduced, and the production cost can be reduced.

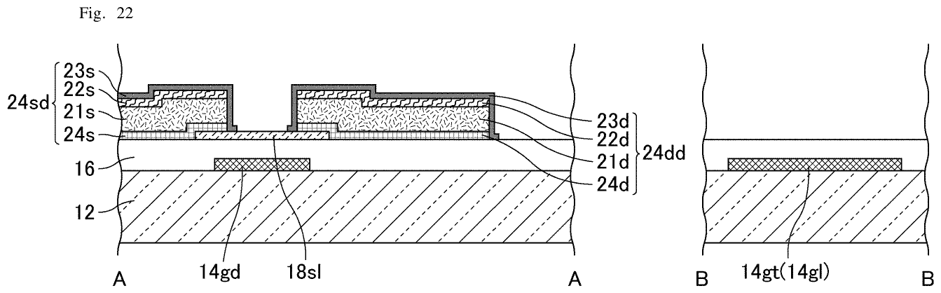

Next, the laminated conductive film 23 is patterned using the resist pattern together with the previously-formed molybdenum nitride layers 24s and 24d, aluminum layers 21s and 21d, and molybdenum nitride layers 22s and 22m as masks by RIE. Accordingly, the source line 24sl, the source electrode 24sd, the drain electrode 24dd, and the source terminal 24st are simultaneously formed as shown in FIG. 22.

The RIE is performed using, for example, a mixed gas containing Cl₂ (flow rate: about 100 sccm) and BCl₃ (flow rate: about 100 sccm) as a raw material gas at a chamber inner pressure of about 4 Pa and a high frequency power of about 1100 W, for example.

### <Fifth to Eighth Patternings>

Thereafter, patternings are performed in the same manner as in the fifth to eighth patternings in Embodiment 1. Accordingly, the TFT substrate 10 shown in FIG. 18 can be produced.

In this embodiment, as in Embodiment 1, the adhesion of the protective insulating film 28 can be ensured. Thus, a reduction in the yield due to delamination of the protective insulating film 28 after the annealing can be prevented, thereby increasing the yield and providing a TFT substrate 10 capable of reducing the resistances of electrodes and lines. Hence, the TFT substrate 10 can be produced at a low cost by using a total of eight (preferably seven) photomasks, and at the same time a decrease in the display quality such as display unevenness of the liquid crystal display device S can be prevented.

In this embodiment, the molybdenum nitride layers 24s and 24d are less likely to cause a redox reaction with the oxide semiconductor than the aluminum layers 21s and 21d. During annealing of the oxide semiconductor layer 18sl after forming the protective insulating film containing silicon oxide 28, the titanium layers are less likely to cause a redox reaction with the oxide semiconductor, and reduction and metallization of the oxide semiconductor layer 18sl by the source electrode 24sd and the drain electrode 24dd can be prevented. Thus, the annealing can satisfactorily repair lattice defects in the oxide semiconductor layer 18sl and reliably stabilize the properties, e.g., the threshold value, of the oxide semiconductor layer 18sl. The metal particles of the aluminum layers 21s and 21d are less likely to diffuse into the molybdenum nitride layers 24s and 24d than into the titanium layers 23s and 23d. Thus, during the annealing, the metal particles of the aluminum layers 21s and 21d are prevented from diffusing into the molybdenum nitride layers 24s and 24d, thereby preventing an elevation in the resistances of the source electrode 24sd, drain electrode 24dd, and source line 24sl. This enables production of a TFT substrate 10 capable of reducing the resistances of electrodes and lines, even in the case where the TFT substrate 10 includes the molybdenum nitride layers 24s and 24d.

In this embodiment, as in Embodiment 1, the source electrode 24sd and the drain electrode 24dd can maintain the good tapered shapes. Thus, the characteristic threshold voltage of the TFT 26 is stabilized, so that a decrease in the display quality such as display unevenness of the liquid crystal display device S can be better prevented.

### Embodiment 3

In the present embodiment, the characteristic features of the present embodiment are mainly described and the same points as in Embodiments 1 and 2 are not described. The components having the same or a similar function have the same reference numerals in both the present embodiment and Embodiments 1 and 2, and such components are not described in the present embodiment. The present embodiment is substantially the same as Embodiment 1, except that the TFTs are etching stopper-type TFTs, as described below.

### <Structure of TFT Substrate 10>

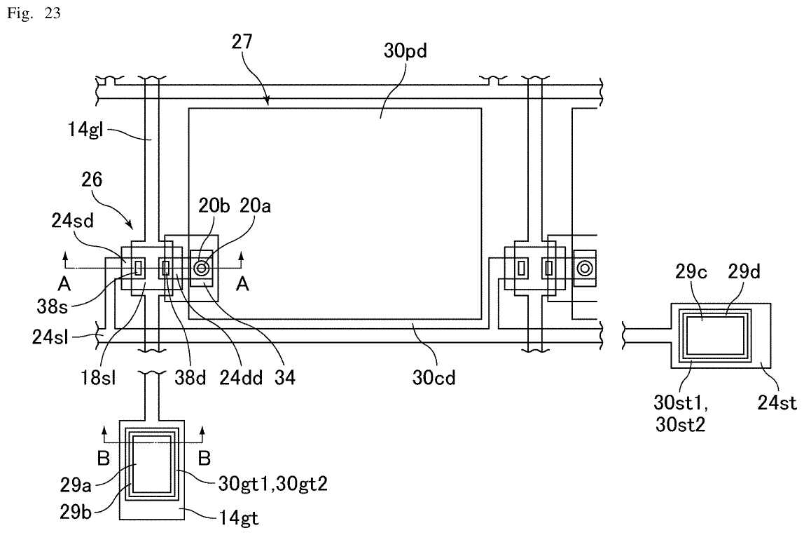

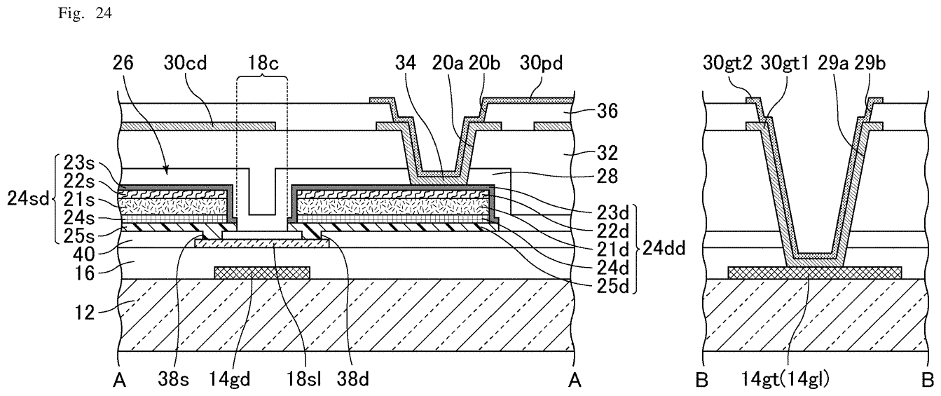

FIG. 23 and FIG. 24 illustrate schematic structures of the TFT substrate 10 according to this embodiment. FIG. 23 is a plan view showing one pixel and ends of lines. FIG. 24 is a cross-sectional view showing the cross-sectional structures taken along the line A-A and the line B-B in this order from left in FIG. 23.

As shown in FIG. 23, the TFT substrate 10 in this embodiment has a plan face layout similar to that of the TFT substrate 10 of Embodiment 1, except that the contact holes 38s and 38d are formed in the below-mentioned etching stopper layer so as to overlap the source electrode 24sd and the drain electrode 24dd.

As shown in FIG. 24, a silicon oxide (SiO₂)-based etching stopper layer 40 covers the oxide semiconductor layer 18sl and the gate insulating film 16, except for regions for the contact holes 38s and 38d.

The source electrode 24sd and the drain electrode 24dd are disposed on the etching stopper layer 40 and are connected to the oxide semiconductor layer 18sl via the contact holes 38s and 38d in the etching stopper layer 40.

The contact hole 29a for connection of the gate connection electrode 30gt1 is provided in the gate insulating film 16, the etching stopper layer 40, and the protective insulating film 28.

### —Production Method—

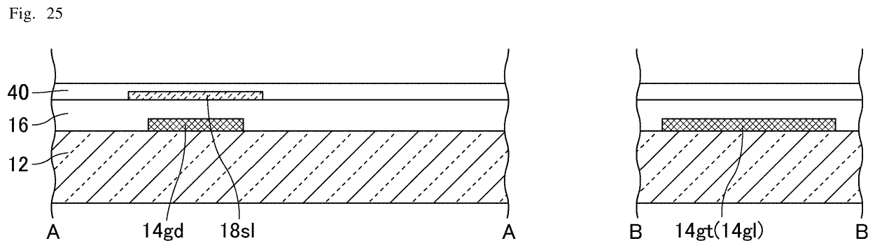

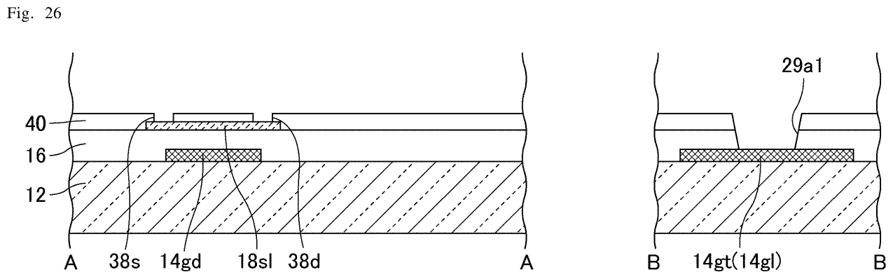

An example of a method for producing the TFT substrate 10 of this embodiment will be described below with reference to FIGS. 25 and 26. FIGS. 25 and 26 are cross-sectional views of the regions shown in FIG. 24 showing third patterning in the production method of the TFT substrate 10.

### <Production of TFT Substrate>

The production of the TFT substrate includes first patterning to ninth patterning.

### <First and Second Patternings>

First, the first patterning and the second patterning are performed as in Embodiment 1.

### <Third Patterning>

A silicon oxide film is formed by CVD on the substrate with the oxide semiconductor layer 18sl, thereby forming the etching stopper layer 40 (thickness: for example, about 200 nm) as shown in FIG. 25.

Then, a resist pattern with openings in the regions for forming the contact holes 29a, 38s, and 38d is formed on the substrate with the etching stopper layer 40 by photolithography using a third photomask. Using the resist pattern as a mask, the gate insulating film 16 and the etching stopper layer 40 are patterned by RIE with a fluorine-based gas, whereby openings 29a1 for forming the contact holes 38s and 38d and the contact hole 29a are formed as shown in FIG. 26.

### <Fourth and Fifth Patternings>

Next, patternings are performed in the same manner as in the third patterning and the fourth patterning in Embodiment 1. The etching stopper layer 40 serves as a channel protective film of the oxide semiconductor layer 18sl. Thus, damage by plasma can be prevented at the channel region 18c of the oxide semiconductor layer 18sl during patterning of the titanium film 25 and the and laminated conductive film 23 by RIE.

### <Sixth Patterning (Formation of Protective Insulating Film and Annealing)>

Subsequently, patterning is performed in the same manner as in the fifth patterning (formation of protective insulating film and annealing) in Embodiment 1. The etching stopper layer 40 containing silicon oxide generally has a higher oxygen permeability than a silicon nitride film, for example. Thus, during annealing, oxygen used in the annealing is effectively supplied to the channel region 18c of the oxide semiconductor layer 18sl. Consequently, lattice defects due to oxygen deficiency potentially existing in the oxide semiconductor layer 18sl are repaired, whereby the properties of the semiconductor layer 18sl can be better stabilized.

### <Seventh to Ninth Patternings>

Thereafter, patternings are performed in the same manner as in the sixth patterning to the eighth patterning in Embodiment 1 are performed. Accordingly, the TFT substrate 10 shown in FIG. 24 can be produced.

In this embodiment, as in Embodiment 1, the adhesion of the protective insulating film 28 can be ensured. Thus, a reduction in the yield due to delamination of the protective insulating film 28 after the annealing can be prevented, thereby increasing the yield and providing a TFT substrate 10 capable of reducing the resistances of electrodes and lines. Hence, the TFT substrate 10 can be produced at a low cost by using a total of nine (preferably eight) photomasks, and at the same time a decrease in the display quality such as display unevenness of the liquid crystal display device S can be prevented.

In this embodiment, as in Embodiment 1, the source electrode 24sd and the drain electrode 24dd can maintain the good tapered shapes. Thus, the characteristic threshold voltage of the TFT 26 is stabilized, so that a decrease in the display quality such as display unevenness of the liquid crystal display device S can be better prevented.

### Embodiment 4

In the present embodiment, the characteristic features of the present embodiment are mainly described and the same points as in Embodiments 1 to 3 are not described. The components having the same or a similar function have the same reference numerals in both the present embodiment and Embodiments 1 to 3, and such components are not described in the present embodiment. The present embodiment is substantially the same as Embodiment 1, except that the fifth conductive layer is not present and the TFT is an etching stopper-type TFT as described below. In other words, the present embodiment is a combination of Embodiments 2 and 3.

### <Structure of TFT Substrate 10>

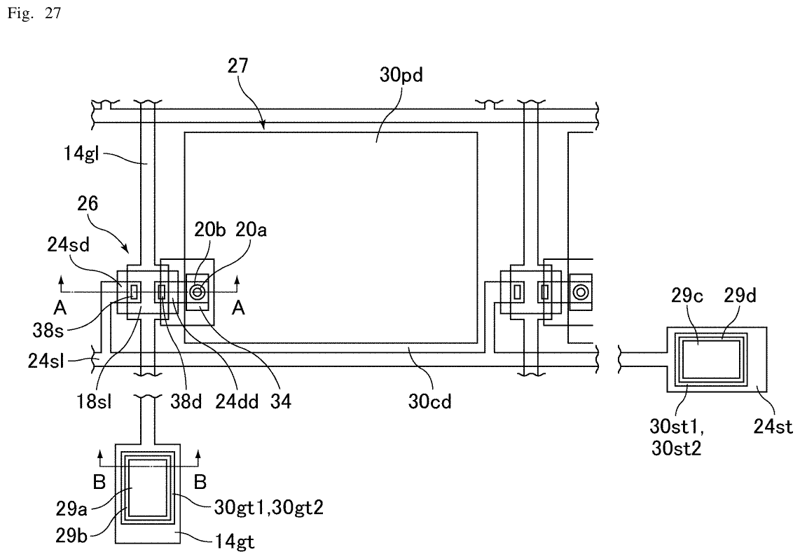

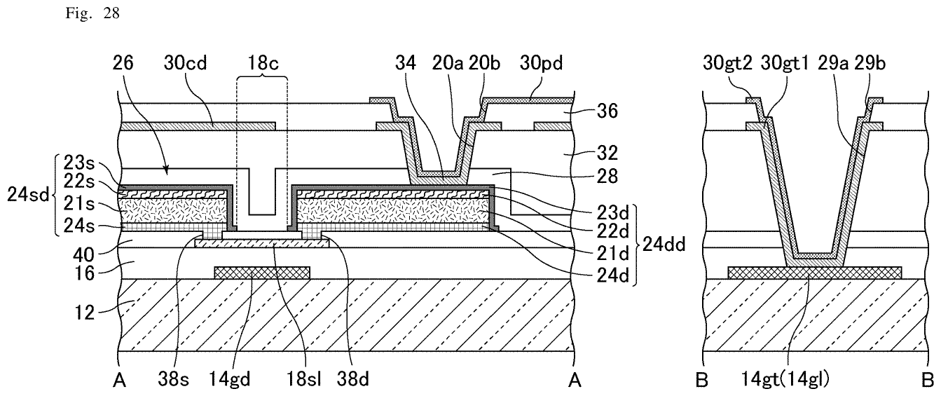

FIG. 27 and FIG. 28 illustrate schematic structures of the TFT substrate 10 according to this embodiment. FIG. 27 is a plan view showing one pixel and ends of lines. FIG. 28 is a cross-sectional view showing the cross-sectional structures taken along the line A-A and the line B-B from left in FIG. 27.

As shown in FIG. 27, the TFT substrate 10 in this embodiment has a plan face layout similar to that of the TFT substrate 10 of Embodiment 1, except that the contact holes 38s and 38d are disposed in the below-mentioned etching stopper layer.

As shown in FIG. 28, the source electrode 24sd and the drain electrode 24dd in the TFT substrate 10 do not include the fifth conductive layer, and each include: a laminate including a molybdenum nitride layer 24s or 24d as a fourth conductive layer, an aluminum layer 21s or 21d as a first conductive layer, and a molybdenum nitride layer 22s or 22d as a second conductive layer stacked in the stated order; and a titanium nitride/titanium layer 23s or 23d as a third conductive layer which is provided so as to cover the laminate. The titanium nitride/titanium layers 23s and 23d cover the upper face and side faces of the laminate.

As shown in FIG. 28, a silicon oxide (SiO₂)-based etching stopper layer 40 covers the oxide semiconductor layer 18sl and gate insulating film 16, except for the regions for the contact holes 38s and 38d.

The source electrode 24sd and the drain electrode 24dd are disposed on the etching stopper layer 40 and are connected to the oxide semiconductor layer 18sl via the contact holes 38s and 38d in the etching stopper layer 40.

### —Production Method—

An example of a method for producing the TFT substrate 10 of this embodiment will be described below.

### <Production of TFT Substrate>

The production of the TFT substrate includes first patterning to ninth patterning.

### <First and Second Patternings>

First, the first patterning and the second patterning are performed as in Embodiment 1.

### <Third Patterning>

Next, the third patterning is performed as in Embodiment 3.

### <Fourth to Fifth Patternings>

Next, the third patterning and the fourth patterning in Embodiment 2 are performed.

### <Sixth to Ninth Patternings>

Next, the fifth patterning to eighth patterning in Embodiment 1 are performed. Accordingly, the TFT substrate 10 shown in FIG. 27 can be produced.

In this embodiment, as in Embodiment 1, the adhesion of the protective insulating film 28 can be ensured. Thus, a reduction in the yield due to delamination of the protective insulating film 28 after the annealing can be prevented, thereby increasing the yield and providing a TFT substrate 10 capable of reducing the resistances of electrodes and lines. Hence, the TFT substrate 10 can be produced at a low cost by using a total of nine (preferably eight) photomasks, and at the same time a decrease in the display quality such as display unevenness of the liquid crystal display device S can be prevented.

In this embodiment, as in Embodiment 1, the source electrode 24sd and the drain electrode 24dd can maintain the good tapered shapes. Thus, the characteristic threshold voltage of the TFT 26 is stabilized, so that a decrease in the display quality such as display unevenness of the liquid crystal display device S can be better prevented.

The above embodiment is an example in which the source electrode 24sd and the drain electrode 24dd each have a stacked structure (TiN/Ti/MoN/Al/MoN/Ti), that is, the source electrode 24sd and the drain electrode 24dd each include: the aluminum layer 21s or the aluminum layer 21d as a first conductive layer; the molybdenum nitride layer 22s or the molybdenum nitride layer 22d as a second conductive layer; the titanium nitride/titanium layer 23s or the titanium nitride/titanium layer 23d as a third conductive layer; the molybdenum nitride layer 24s or the molybdenum nitride layer 24d as a fourth conductive layer; and the titanium layer 25s or the titanium layer 25d as a fifth conductive layer. Yet, the present invention is not limited to the example.

The first conductive layers 21s and 21d may contain any other low resist metal material having a specific resistance of 5 μΩ·cm or less, such as copper (Cu) or silver (Ag), instead of aluminum (Al).

Instead of molybdenum nitride (MoN), the second conductive layers 22s and 22d may contain a refractory metal such as molybdenum (Mo) or an alloy primarily containing molybdenum, or chromium (Cr), niobium (Nb), tantalum (Ta), or tungsten (W), or an alloy primarily containing any of these elements, or a nitride or oxide thereof. The second conductive layers 22s and 22d each contain a Group 5 or Group 6 metal element, an alloy primarily containing a Group 5 or Group 6 metal element, or a nitride or oxide thereof.

Instead of titanium nitride (TiN)/titanium (Ti), the third conductive layers 23s and 23d may contain a refractory metal such as titanium (Ti), titanium nitride (TiN), titanium oxide (TiO), or an alloy primarily containing titanium (Ti). The third conductive layers 23s and 23d each contain at least a Group 4 metal element, an alloy primarily containing the metal element, or a nitride or oxide thereof. The fifth conductive layers 25s and 25d may consist of, for example, a titanium film (thickness: for example, about 30 nm).

Instead of molybdenum nitride (MoN), the fourth conductive layers 24s and 24d may contain a refractory metal such as molybdenum (Mo) or an alloy primarily containing molybdenum, or chromium (Cr), niobium (Nb), tantalum (Ta), or tungsten (W), an alloy primarily containing any of these elements, or a nitride or oxide thereof. The fourth conductive layers 24s and 24d each contain at least a Group 5 or Group 6 metal element, an alloy primarily containing the metal element, or a nitride or oxide thereof.

Instead of titanium (Ti), the fifth conductive layers 25s and 25d may contain a refractory metal such as titanium nitride (TiN), titanium oxide (TiO), or an alloy primarily containing titanium (Ti). The fifth conductive layers 25s and 25d each contain at least a Group 4 metal element, an alloy primarily containing the metal element, or a nitride or oxide thereof.

Specific other examples of the stacked structures of the source electrode 24sd and the drain electrode 24dd include a stacked structure in which the lowermost titanium layer 25s or 25d is replaced with a tungsten layer (TiN/Ti/MoN/Al/MoN/W) or a tantalum layer (TiN/Ti/MoN/Al/MoN/Ta).

In the present embodiment, the TFT including an In—Ga—Zn—O-based oxide semiconductor layer is described as an example. The present invention may also be applied to a TFT substrate including a TFT that includes any other oxide semiconductor layer, such as an indium silicon zinc oxide (In—Si—Zn—O)—, indium aluminum zinc oxide (In—Al—Zn—O)—, tin silicon zinc oxide (Sn—Si—Zn—O)—, tin aluminum zinc oxide (Sn—Al—Zn—O)—, tin gallium zinc oxide (Sn-Ga—Zn-O)—, gallium silicon zinc oxide (Ga—Si—Zn—O)—, gallium aluminum zinc oxide (Ga—Al—Zn—O)—, indium copper zinc oxide (In—Cu—Zn—O)—, tin copper zinc oxide (Sn—Cu—Zn—O)—, tin oxide (Zn—O)—, or indium oxide (In—O)-based oxide semiconductor layer.

In the present embodiment, the annealing in the production of the TFT substrate is performed after forming the protective insulating film 28 but before forming a contact hole in the protective insulating film 28. Alternatively, the annealing may be performed after forming a contact hole in the protective insulating film 28.

The present invention is not limited to the above embodiments each giving an example where the TFT substrate 10 constitutes the transmissive liquid crystal display device S. The TFT substrate 10 of the present invention may be applied to other types of display devices such as reflective liquid crystal display devices, trans-reflective liquid crystal display devices, and organic electroluminescent (EL) display devices, and methods for producing these devices.

### [Additional Remarks]

The first embodiment of the present invention may be a TFT substrate (10), including a base substrate (12), a TFT (26) including: a gate electrode (14gd) provided on the base substrate (12); a gate insulating film (16) covering the gate electrode (14gd); a semiconductor layer (18sl) containing an oxide semiconductor and provided on the gate insulating film (16) so as to overlap the gate electrode (14gd); and a source electrode (24sd) and a drain electrode (24dd) which are provided so that a part of the source electrode and a part of the drain electrode are connected to the semiconductor layer (18sl) and so as to face each other on the semiconductor layer (18sl), and a protective insulating film containing silicon oxide (28) covering the TFT (26),

wherein the source electrode (24sd) and the drain electrode (24dd) each include a laminate of a first conductive layer (21s, 21d) and a second conductive layer (22s, 22d) stacked in the stated order and a third conductive layer (23s, 23d) covering the laminate, each first conductive layer (21s, 21d) contains a low resistance metal including at least one element selected from aluminum, copper, and silver,

each second conductive layer (22s, 22d) contains a refractory metal including a Group 5 or Group 6 metal element, an alloy primarily containing the metal element, or a nitride or oxide thereof, the refractory metal being less likely to allow metal particles of the first conductive layer (21s, 21d) to diffuse than the third conductive layer (23s, 23d), and

each third conductive layer (23s, 23d) directly contacts the protective insulating film (28) and contains a refractory metal including a Group 4 metal element, an alloy primarily containing the metal element, or a nitride or oxide thereof, the refractory metal being less likely to cause a redox reaction with silicon oxide than the second conductive layer (22s, 22d).

In this structure, the third conductive layers (23s, 23d) contain a refractory metal element including a Group 4 metal element that is less likely to cause a redox reaction with silicon oxide than the second conductive layer (22s, 22d), and also cover the second conductive layers (22s, 22d) which cause a redox reaction with the protective insulating film containing silicon oxide (28). During annealing of the oxide semiconductor layer (18sl) after forming the protective insulating film containing silicon oxide (28), the second conductive layers (22s, 22d) are less likely to cause a redox reaction with the protective insulating film containing silicon oxide (28), so that the adhesion of the protective insulating film (28) can be ensured. Thus, a reduction in the yield due to delamination of the protective insulating film (28) can be prevented. Additionally, the metal particles of the first conductive layers (21s, 21d) are less likely to diffuse into the second conductive layers (22s, 22d), which contain a refractory metal including a Group 5 or Group 6 metal element, than into the third conductive layers (23s, 23d). Thus, during the annealing, the metal particles of the first conductive layers (21s, 21d) are prevented from diffusing into the second conductive layers (22s, 22d). The second conductive layers (22s, 22d) can prevent the metal particles of the first conductive layers (21s, 21d) from diffusing into the third conductive layers (23s, 23d), thereby preventing an elevation in the resistances of the source electrode (24sd) and the drain electrode (24dd). This can increase the yield and provide a TFT substrate (10) capable of reducing the resistances of electrodes.

According to the second embodiment of the present invention, the second conductive layer (22s, 22d) in the TFT substrate (10) of the first embodiment of the present invention may contain at least one element selected from molybdenum (Mo), chromium (Cr), niobium (Nb), tantalum (Ta), and tungsten (W), and the third conductive layer (23s, 23d) may contain titanium (Ti).

With this structure, the effects of the present invention are specifically exhibited.

According to the third embodiment of the present invention, the source electrode (24sd) and the drain electrode (24dd) in the TFT substrate (10) of the first or second embodiment of the present invention may each further include a fourth conductive layer (24s, 24d) and a fifth conductive layer (25s, 25d),

the laminate includes the fourth conductive layer (24s, 24d), the first conductive layer (21s, 21d), and the second conductive layer (22s, 22d) stacked in the stated order and is disposed between the fifth conductive layer (25s, 25d) and the third conductive layer (23s, 23d),

each fourth conductive layer (24s, 24d) contains a refractory metal including a Group 5 or Group 6 metal element, an alloy primarily containing the metal element, or a nitride or oxide thereof, the refractory metal being less likely to allow metal particles of the first conductive layer (21s, 21d) to diffuse than the fifth conductive layer (25s, 25d), and

each fifth conductive layer (25s, 25d) is directly connected to the semiconductor layer (18sl) and contains a refractory metal including a Group 4 metal element, an alloy primarily containing the metal element, or a nitride or oxide thereof, the refractory metal being less likely to cause a redox reaction with silicon oxide than the first conductive layer (22s, 22d).

In this structure, the fifth conductive layers (25s, 25d) contain a refractory metal element including a Group 4 metal element that is less likely to cause a redox reaction with the oxide semiconductor than the first conductive layers (21s, 21d). During annealing of the oxide semiconductor layer (18sl) after forming the protective insulating film containing silicon oxide (28), the fifth conductive layers are less likely to cause a redox reaction with the oxide semiconductor, and reduction and metallization of the oxide semiconductor layer (18sl) by the source electrode (24sd) and the drain electrode (24dd) can be prevented. Thus, the annealing can satisfactorily repair lattice defects in the oxide semiconductor layer (18sl) and reliably stabilize the properties, e.g., the threshold value, of the oxide semiconductor layer (18sl). Additionally, the metal particles of the first conductive layers (21s, 21d) are less likely to diffuse into the fourth conductive layers (24s, 24d), which contain a refractory metal including a Group 5 or Group 6 metal element, than into the fifth conductive layers (25s, 25d). Thus, during the annealing, the metal particles of the first conductive layers (21s, 21d) are prevented from diffusing into the fourth conductive layers (24s, 24d). The fourth conductive layers (24s, 24d) can prevent the metal particles of the first conductive layers (21s, 21d) from diffusing into the fifth conductive layers (25s, 25d), thereby preventing an elevation in the resistances of the source electrode (24sd) and the drain electrode (24dd). This can provide a TFT substrate (10) capable of reducing the resistances of electrodes, even in the case where the TFT substrate (10) includes the fourth conductive layers (24s, 24d) and the fifth conductive layers (25s, 25d).

According to the fourth embodiment of the present invention, the fourth conductive layers (24s, 24d) in the TFT substrate (10) of the third embodiment of the present invention may contain at least one element selected from molybdenum (Mo), chromium (Cr), niobium (Nb), tantalum (Ta), and tungsten (W), and the fifth conductive layers (25s, 25d) may contain titanium (Ti).

With this structure, the effects of the third embodiment of the present invention are specifically exhibited.

According to the fifth embodiment of the present invention, the source electrode (24sd) and the drain electrode (24dd) in the TFT substrate (10) of the first or second embodiment of the present invention may each further include a fourth conductive layer (24s, 24d), the laminate includes the fourth conductive layer (24s, 24d), the first conductive layer (21s, 21d), and the second conductive layer (22s, 22d) stacked in the stated order, and the fourth conductive layer (24s, 24d) is directly connected to the semiconductor layer (18sl) and contains a refractory metal including a Group 5 or Group 6 metal element, an alloy primarily containing the metal element, or a nitride or oxide thereof, the refractory metal being less likely to cause a redox reaction with the oxide semiconductor than the first conductive layer (21s, 21d) and less likely to allow metal particles of the first conductive layer (21s, 21d) to diffuse than the third conductive layer (23s, 23d).

In this structure, the fourth conductive layers (24s, 24d) contain a refractory metal element including a Group 5 or Group 6 metal element that is less likely to cause a redox reaction with the oxide semiconductor than the first conductive layers (21s, 21d). During annealing of the oxide semiconductor layer (18sl) after forming the protective insulating film containing silicon oxide (28), the fourth conductive layers are less likely to cause a redox reaction with the oxide semiconductor, and reduction and metallization of the oxide semiconductor layer (18sl) by the source electrode (24sd) and the drain electrode (24dd) can be prevented. Thus, the annealing can satisfactorily repair lattice defects in the oxide semiconductor layer (18sl) and reliably stabilize the properties, e.g., the threshold value, of the oxide semiconductor layer (18sl). Additionally, the metal particles of the first conductive layers (21s, 21d) are less likely to diffuse into the fourth conductive layers (24s, 24d), which contain a refractory metal including a Group 5 or Group 6 metal element, than into the third conductive layers (23s, 23d). Thus, during the annealing, the metal particles of the first conductive layers (21s, 21d) are prevented from diffusing into the fourth conductive layers (24s, 24d), thereby preventing an elevation in the resistances of the source electrode (24sd) and the drain electrode (24dd). This can provide a TFT substrate (10) capable of reducing the resistances of electrodes, even in the case where the TFT substrate (10) includes the fourth conductive layers (24s, 24d).

According to the sixth embodiment of the present invention, the fourth conductive layer (24s, 24d) in the TFT substrate (10) of the fifth embodiment may contain at least one element selected from molybdenum (Mo), chromium (Cr), niobium (Nb), tantalum (Ta), and tungsten (W).

With this structure, the effects of the fifth embodiment of the present invention are specifically exhibited.

According to the seventh embodiment of the present invention, the semiconductor layer (18sl) in the TFT substrate (10) of any one of the first to sixth embodiments may include an In—Ga—Zn—O-based oxide semiconductor.

With this structure, the TFT (26) can specifically obtain the advantageous properties of high carrier mobility, high reliability, and low off-current.

The eighth embodiment of the present invention may be a liquid crystal display device (S) including the TFT substrate according to any one of the first to seventh embodiments of the present invention; a counter substrate (50) facing the TFT substrate (10), and a liquid crystal layer (52) disposed between the TFT substrate (10) and the counter substrate (50).

With this structure, the TFT substrate (10) of the first to seventh invention can increase the yield and can reduce the resistances of electrodes. This can suppress a decrease in the display quality due to, for example, display unevenness, while reducing the production cost of the liquid crystal display device (S).

The ninth embodiment of the present invention may be a method for producing a TFT substrate (10), including: first patterning including forming a conductive film on a base substrate (12) and patterning the conductive film using a first photomask to form a gate electrode (14gd);

gate insulating film formation including forming a gate insulating film (16) so as to cover the gate electrode (14gd);

second patterning including forming a semiconductor film from an oxide semiconductor on the gate insulating film (16) and patterning the semiconductor film using a second photomask to form a semiconductor layer (18sl);

third patterning including forming a first conductive film (21) containing a low resistance metal including at least one element selected from aluminum, copper, and silver and a second conductive film (22) containing a refractory metal including a Group 5 or Group 6 metal element, an alloy primarily containing the metal element, or a nitride or oxide thereof in the stated order so as to cover the semiconductor layer (18sl), and patterning the first conductive film (21) and the second conductive film (22) by wet etching using a third photomask;

fourth patterning including, after patterning the first conductive film (21) and the second conductive film (22), forming a third conductive film (23) containing a refractory metal including a Group 4 metal element, an alloy primarily containing the metal element, or a nitride or oxide thereof and patterning the third conductive film (23) by dry etching to form a source electrode (24sd) and a drain electrode (24dd);

protective insulating film formation including forming a protective insulating film containing silicon oxide (28) so as to cover the source electrode (24sd) and the drain electrode (24dd); and anneal treatment including annealing the substrate with the protective insulating film (28).

In the production method, the third conductive film (23) contains a refractory metal element including a Group 4 metal element that is less likely to cause a redox reaction with silicon oxide than the second conductive film (22). During annealing, the second conductive layers (22s, 22d) are less likely to cause a redox reaction with the protective insulating film containing silicon oxide (28), so that the adhesion of the protective insulating film (28) can be ensured. Thus, a reduction in the yield due to delamination of the protective insulating film (28) after the annealing can be prevented. Additionally, the metal particles of the first conductive film (21) are less likely to diffuse into the second conductive film (22), which contains a refractory metal including a Group 5 or Group 6 metal element, than into the third conductive film (23). Thus, during the annealing, the second conductive layers (22s, 22d) prevent the metal particles of the first conductive layers (21s, 21d) from diffusing into the third conductive layers (23s, 23d), thereby preventing an elevation in the resistances of the source electrode (24sd) and the drain electrode (24dd). This can increase the yield and provide a TFT substrate (10) capable of reducing the resistances of electrodes.

The 10th embodiment of the present invention may be the method for producing a TFT substrate (10) of the ninth embodiment of the present invention in which the third conductive film (23) is patterned using the third photomask in the fourth patterning third photomask.

The production method can reduce the number of photomasks as compared to the case where another photomask for patterning the third conductive film (23) is used, thereby reducing the production cost.

The 11th embodiment of the present invention may be the method for producing a TFT substrate (10) of the ninth or 10th embodiment of the present invention in which the third patterning includes, before forming the first conductive film (21), forming a fifth conductive film (25) containing a refractory metal including a Group 4 metal element, an alloy primarily containing the metal element, or a nitride or oxide thereof and a fourth conductive film (24) containing a refractory metal including a Group 5 or Group 6 metal element, an alloy primarily containing the metal element, or a nitride or oxide thereof in the stated order so as to cover the semiconductor layer (18sl), and the fourth patterning includes patterning the third conductive film (23) and the fifth conductive film (25) by dry etching.

In the production method, the fifth conductive film (25) contains a refractory metal element including a Group 4 metal element that is less likely to cause a redox reaction with the oxide semiconductor than the first conductive film (21). During annealing of the oxide semiconductor layer (18sl) after forming the protective insulating film containing silicon oxide (28), the fifth conductive film is less likely to cause a redox reaction with the oxide semiconductor, and reduction and metallization of the oxide semiconductor layer (18sl) by the source electrode (24sd) and the drain electrode (24dd) can be prevented. Thus, the annealing can satisfactorily repair lattice defects in the oxide semiconductor layer (18sl) and reliably stabilize the properties, e.g., the threshold value, of the oxide semiconductor layer (18sl). Additionally, the metal particles of the first conductive film (21) are less likely to diffuse into the fourth conductive film (24), which contains a refractory metal including a Group 5 or Group 6 metal element, than into the fifth conductive film (25). Thus, during the annealing, the metal particles of the first conductive layers are prevented from diffusing into the fourth conductive layers (24s, 24d). The fourth conductive layers (24s, 24d) can prevent the metal particles of the first conductive layers (21s, 21d) from diffusing into the fifth conductive layers (25s, 25d), thereby preventing an elevation in the resistances of the source electrode (24sd) and the drain electrode (24dd). This can provide a TFT substrate (10) capable of reducing the resistances of electrodes, even in the case where the TFT substrate (10) includes the fourth conductive layers (24s, 24d) and the fifth conductive layers (25s, 25d).

The 12th embodiment of the present invention may be the method for producing a TFT substrate (10) of the ninth or 10th embodiment of the present invention in which the third patterning includes, before forming the first conductive film (21), forming a fourth conductive film (24) containing a refractory metal including a Group 5 or Group 6 metal element, an alloy primarily containing the metal element or a nitride or oxide thereof, and the third conductive film (23) is patterned by dry etching in the fourth patterning.

In the production method, the fourth conductive film (24) contains a refractory metal element including a Group 5 or Group 6 metal element that is less likely to cause a redox reaction with the oxide semiconductor than the first conductive film (21). During annealing of the oxide semiconductor layer (18sl) after forming the protective insulating film containing silicon oxide (28), the fourth conductive film is less likely to cause a redox reaction with the oxide semiconductor, and reduction and metallization of the oxide semiconductor layer (18sl) by the source electrode (24sd) and the drain electrode (24dd) can be prevented. Thus, the annealing can satisfactorily repair lattice defects in the oxide semiconductor layer (18sl) and reliably stabilize the properties, e.g., the threshold value, of the oxide semiconductor layer (18sl). Additionally, the metal particles of the first conductive film (21) are less likely to diffuse into the fourth conductive film (24), which contains a refractory metal including a Group 5 or Group 6 metal element, than into the third conductive film (23). Thus, during the annealing, the metal particles of the first conductive layers (21s, 21d) are prevented from diffusing into the fourth conductive layers (24s, 24d), thereby preventing an elevation in the resistances of the source electrode (24sd) and the drain electrode (24dd). This can provide a TFT substrate (10) capable of reducing the resistances of electrodes, even in the case where the TFT substrate (10) includes the fourth conductive layers (24s, 24d) and the fifth conductive layers (25s, 25d).

The 13th embodiment of the present invention may be the method for producing the TFT substrate (10) of any one of the ninth to 12th embodiments of the present invention in which the oxide semiconductor includes an In—Ga—Zn—O-based oxide semiconductor.

The TFT (26) produced by the production method specifically obtains the good properties of high carrier mobility, high reliability, and low off-current.

The above embodiments of the present invention may appropriately be combined with each other within the spirit of the present invention.

### REFERENCE SIGNS LIST

10: TFT substrate (thin-film transistor substrate)
12: insulating substrate (base substrate)
14gd: gate electrode
16: gate insulator
18sl: oxide semiconductor layer
20a, 20b, 29a, 29b, 38s, 38d: contact hole
21: aluminum film (first conductive film)
22: molybdenum nitride film (second conductive film)
23: laminated conductive film (third conductive film)
24: molybdenum nitride film (fourth conductive film)
25: titanium film (fifth conductive film)
24sd: source electrode
24dd: drain electrode
21s, 21d: aluminum layer (first conductive layer)
22s, 22d: molybdenum nitride layer (second conductive layer)
23s, 23d: titanium nitride/titanium layer (third conductive layer)
24s, 24d: molybdenum nitride layer (fourth conductive layer)
25s, 25d: titanium layer (fifth conductive layer)
26: TFT (thin-film transistor)
28, 32, 36: protective insulating film
30cd: common electrode (transparent conductive layer)
30pd: pixel electrode (transparent conductive layer)
34: connection electrode
40: etching stopper layer
50: counter substrate
52: liquid crystal layer
S: liquid crystal display device

1. A thin-film transistor substrate, comprising
a base substrate,
a thin-film transistor comprising: a gate electrode provided on the base substrate; a gate insulating film covering the gate electrode; a semiconductor layer comprising an oxide semiconductor and provided on the gate insulating film so as to overlap the gate electrode; and a source electrode and a drain electrode which are provided so that a part of the source electrode and a part of the drain electrode are connected to the semiconductor layer and so as to face each other on the semiconductor layer, and
a protective insulating film comprising silicon oxide covering the thin-film transistor,
wherein the source electrode and the drain electrode each comprise a laminate of a first conductive layer and a second conductive layer stacked in the stated order and a third conductive layer covering the laminate,
each first conductive layer comprises a low resistance metal including at least one element selected from aluminum, copper, and silver,
each second conductive layer comprises a refractory metal including a Group 5 or Group 6 metal element, an alloy primarily containing the metal element, or a nitride or oxide thereof, the refractory metal being less likely to allow metal particles of the first conductive layer to diffuse than the third layer, and
each third conductive layer directly contacts the protective insulating film and comprises a refractory metal including a Group 4 metal element, an alloy primarily containing the metal element, or a nitride or oxide thereof, the refractory metal being less likely to cause a redox reaction with silicon oxide than the second conductive layer.

2. The thin-film transistor substrate according to claim 1,
wherein the second conductive layer comprises at least one element selected from molybdenum, chromium, niobium, tantalum, and tungsten, and
the third conductive layer comprises titanium.

3. The thin-film transistor substrate according to claim 1,
wherein the source electrode and the drain electrode each further comprise a fourth conductive layer and a fifth conductive layer,
the laminate comprises the fourth conductive layer, the first conductive layer, and the second conductive layer stacked in the stated order and is disposed between the fifth conductive layer and the third conductive layer,
each fourth conductive layer comprises a refractory metal including a Group 5 or Group 6 metal element, an alloy primarily containing the metal element, or a nitride or oxide thereof, the refractory metal being less likely to allow metal particles of the first conductive layer to diffuse than the fifth conductive layer, and
each fifth conductive layer is directly connected to the semiconductor layer and comprises a refractory metal including a Group 4 metal element, an alloy primarily containing the metal element, or a nitride or oxide thereof, the refractory metal being less likely to cause a redox reaction with silicon oxide than the first conductive layer.

4. A thin-film transistor substrate according to claim 3,
wherein the fourth conductive layer comprises at least one element selected from molybdenum, chromium, niobium, tantalum, and tungsten, and
the fifth conductive layer comprises titanium.

5. The thin-film transistor substrate according to claim 1,
wherein the source electrode and the drain electrode each further comprise a fourth conductive layer,
the laminate comprises the fourth conductive layer, the first conductive layer, and the second conductive layer stacked in the stated order, and
the fourth conductive layer is directly connected to the semiconductor layer and comprises a refractory metal including a Group 5 or Group 6 metal element, an alloy primarily containing the metal element, or a nitride or oxide thereof, the refractory metal being less likely to cause a redox reaction with the oxide semiconductor than the first conductive layer and less likely to allow metal particles of the first conductive layer to diffuse than the third conductive layer.

6. The thin-film transistor substrate according to claim 5,
wherein the fourth conductive layer comprises at least one element selected from molybdenum, chromium, niobium, tantalum, and tungsten.

7. The thin-film transistor substrate according to claim 1,
wherein the semiconductor layer comprises an indium-gallium-zinc oxide-based oxide semiconductor.

8. A liquid crystal display device, comprising:
the thin-film transistor substrate according to claim 1;
a counter substrate facing the thin-film transistor substrate; and
a liquid crystal layer disposed between the thin-film transistor substrate and the counter substrate.

9. A method for producing a thin-film transistor substrate, comprising:
first patterning including forming a conductive film on a base substrate and patterning the conductive film using a first photomask to form a gate electrode;
gate insulating film formation including forming a gate insulating film so as to cover the gate electrode;
second patterning including forming a semiconductor film from an oxide semiconductor on the gate insulating film and patterning the semiconductor film using a second photomask to form a semiconductor layer;
third patterning including forming a first conductive film comprising a low resistance metal comprising at least one element selected from aluminum, copper, and silver and a second conductive film comprising a refractory metal including a Group 5 or Group 6 metal element, an alloy primarily containing the metal element, or a nitride or oxide thereof in the stated order so as to cover the semiconductor layer, and patterning the first conductive film and the second conductive film by wet etching using a third photomask;
fourth patterning including, after patterning the first conductive film and the second conductive film, forming a third conductive film comprising a refractory metal including a Group 4 metal element, an alloy primarily containing the metal element, or a nitride or oxide thereof and patterning the third conductive film by dry etching to form a source electrode and a drain electrode;
protective insulating film formation including forming a protective insulating film containing silicon oxide so as to cover the source electrode and the drain electrode; and
anneal treatment including annealing the substrate with the protective insulating film.

10. The method for producing a thin-film transistor substrate according to claim 9,
wherein the third conductive film is patterned using the third photomask in the fourth patterning.

11. The method for producing a thin-film transistor substrate according to claim 9,
wherein the third patterning includes, before forming the first conductive film, forming a fifth conductive film comprising a refractory metal including a Group 4 metal element, an alloy primarily containing the metal element, or a nitride or oxide thereof and a fourth conductive film comprising a refractory metal including a Group 5 or Group 6 metal element, an alloy primarily containing the metal element, or a nitride or oxide thereof in the stated order so as to cover the semiconductor layer, and
the fourth patterning includes patterning the third conductive film and the fifth conductive film by dry etching.

12. The method for producing a thin-film transistor substrate according to claim 9,
wherein the third patterning includes, before forming the first conductive film, forming a fourth conductive film comprising a refractory metal including a Group 5 or Group 6 metal element, an alloy primarily containing the metal element, or a nitride or oxide thereof, and
the third conductive film is patterned by dry etching in the fourth patterning.

13. The method for producing a thin-film transistor substrate according to claim 9,
wherein the oxide semiconductor comprises an indium-gallium-zinc oxide-based oxide semiconductor.
